(19) United States
(12) Patent Application Publication
(10) Pub. No.: US 2026/0114099 A1
(43) Pub. Date: Apr. 23, 2026

(54) DISPLAY DEVICE AND ELECTRONIC DEVICE

(71) Applicant: Samsung Display Co., Ltd., Yongin-si (KR)

(72) Inventors: Soo Chul KIM, Yongin-si (KR); Ki Bum KIM, Yongin-si (KR); Tae Gyun KIM, Yongin-si (KR); So Young LEE, Yongin-si (KR); Won Ho LEE, Yongin-si (KR)

(21) Appl. No.: 19/225,979

(22) Filed: Jun. 2, 2025

(30) Foreign Application Priority Data
Oct. 17, 2024 (KR) 10-2024-0142112

(51) Int. Cl. H10H 29/49; H10H 29/34

(52) U.S. Cl. CPC H10H 29/49; H10H 29/34

(57) ABSTRACT

A display device is provided. The display device includes a backplane substrate including a display area, and a first light-emitting element layer above the backplane substrate, and including a first electrode in a first emission area of the display area, a first light-emitting element above the first electrode, and a first common electrode above the first light-emitting element, and including a first portion in a non-emission area surrounding the first emission area, a second portion above at least a part of the first light-emitting element, and electrically connected to the first light-emitting element, and a third portion between the first portion and the second portion, including first patterns connecting the first portion to the second portion, and defining first openings between the first patterns.

### CROSS-REFERENCE TO RELATED APPLICATION

The present application claims priority to, and the benefit of, Korean Patent Application No. 10-2024-0142112, filed on Oct. 17, 2024, in the Korean Intellectual Property Office, the entire disclosure of which is incorporated herein by reference.

### BACKGROUND

### 1. Field

The present disclosure relates to a display device and an electronic device.

### 2. Description of the Related Art

With the advance of information-oriented society, more and more demands are placed on display devices for displaying images in various ways. Along with this trend, various types of display devices including a light-emitting display device are being developed. The light-emitting display device includes pixels including light-emitting elements.

### SUMMARY

Aspects of the present disclosure provide a display device and an electronic device capable of improving the light efficiency of pixels.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a backplane substrate including a display area, and a first light-emitting element layer above the backplane substrate, and including a first electrode in a first emission area of the display area, a first light-emitting element above the first electrode, and a first common electrode above the first light-emitting element, and including a first portion in a non-emission area surrounding the first emission area, a second portion above at least a part of the first light-emitting element, and electrically connected to the first light-emitting element, and a third portion between the first portion and the second portion, including first patterns connecting the first portion to the second portion, and defining first openings between the first patterns.

The first patterns may be at uniform intervals in at least a part of the third portion.

The first openings may have a planar shape of a slit shape, a mesh shape, a concentric shape, or a dot shape.

The display area may include emission areas including the first emission area, and the non-emission area around the emission areas, wherein the first portion of the first common electrode is entirely in the non-emission area, and surrounds light-emitting elements in the emission areas in plan view.

The first common electrode may have a same planar shape in the emission areas.

The first common electrode may have different respective shapes in at least two of the emission areas for emitting light of different respective colors.

The first common electrode may define an opening in at least one of the emission areas for emitting light of a color that is different from that of light emitted from the first emission area.

The display device may further include a second light-emitting element layer between the backplane substrate and the first light-emitting element layer, and including a second electrode in a second emission area of the display area, a second light-emitting element above the second electrode, and a second common electrode above the second light-emitting element, and including a first portion in the non-emission area, a second portion above at least a part of the second light-emitting element, and electrically connected to the second light-emitting element, and a third portion between the first portion and the second portion, including second patterns connecting the first portion to the second portion, and defining second openings between the second patterns.

The display device may further include a first intermediate electrode connected between the backplane substrate and the first electrode, and including a first conductive layer at a same layer as, and separated from, the second electrode, a second conductive layer at a same layer as, and separated from, the second common electrode, and connection electrodes connecting the first conductive layer, the second conductive layer, and the first electrode.

The first common electrode may have a same planar shape in the first emission area and in the second emission area.

The first common electrode may have different respective planar shapes in the first emission area and in the second emission area.

The first common electrode and the second common electrode may have a same planar shape in the second emission area.

The first common electrode and the second common electrode may have different respective planar shapes in the second emission area.

The first common electrode may define at least one opening in the second emission area.

The display device may further include a floating pattern in the second emission area at a same layer as, and separated from, the first common electrode.

The display device may further include a third light-emitting element layer between the first light-emitting element layer and the second light-emitting element layer, and including a third electrode in a third emission area of the display area, a third light-emitting element above the third electrode, and a third common electrode above the third light-emitting element, and including a first portion in the non-emission area, a second portion above at least a part of the third light-emitting element, and electrically connected to the third light-emitting element, and a third portion between the first portion and the second portion, including third patterns connecting the first portion to the second portion, and defining third openings between the third patterns.

The display device may further include a second intermediate electrode connected between the backplane substrate and the third electrode, and including a first conductive layer at a same layer as, and separated from, the second electrode, a second conductive layer at a same layer as, and separated from, the second common electrode, and connection electrodes connecting the first conductive layer, the second conductive layer, and the third electrode.

The third common electrode may define at least one opening in the second emission area.

The display device may further include a power line in the non-emission area above the backplane substrate, surrounding the light-emitting elements in the emission areas in plan view, and electrically connected to the first common electrode, and a reflective film covering a side surface of the power line.

According to an aspect of the present disclosure, there is provided an electronic device including a processor configured to transmit an image data signal, and a display module configured to receive the image data signal, and including a display panel that includes a backplane substrate including a display area, and a first light-emitting element layer above the backplane substrate, and including a first electrode in a first emission area of the display area, a first light-emitting element above the first electrode, and a first common electrode above the first light-emitting element, and including a first portion in a non-emission area surrounding the first emission area, a second portion above at least a part of the first light-emitting element, and electrically connected to the first light-emitting element, and a third portion between the first portion and the second portion, including first patterns connecting the first portion to the second portion, and defining first openings between the first patterns.

According to the display device and the electronic device according to embodiments, the light efficiency of pixels may be improved.

However, aspects according to the embodiments of the present disclosure are not limited to those described above, and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a plan view illustrating a display area of a display device according to one or more embodiments;

FIG. 3 is a cross-sectional view illustrating a display panel according to one or more embodiments;

FIG. 4 is a cross-sectional view showing a light-emitting element according to one or more embodiments;

FIG. 5 is a plan view illustrating a common electrode connection area of a display device according to one or more embodiments;

FIG. 6 is a cross-sectional view illustrating a display panel according to one or more embodiments;

FIG. 7 is a plan view illustrating a pad area of a display device according to one or more embodiments;

FIG. 8 is a cross-sectional view illustrating a display panel according to one or more embodiments;

FIG. 9 is a plan view illustrating a display area of a display device according to one or more embodiments;

FIGS. 10, 11, and 12 are plan views showing common electrodes according to one or more embodiments;

FIG. 13 is a cross-sectional view illustrating a display panel according to one or more embodiments;

FIG. 14 is a drawing showing a polarization effect obtained by a common electrode according to one or more embodiments; and

FIGS. 15, 16, 17, 18, and 19 are plan views showing common electrodes according to respective embodiments;

FIG. 20 is a diagram illustrating a smart watch including a display device according to one or more embodiments;

FIGS. 21 and 22 illustrate a head-mounted display including a display device according to one or more embodiments;

FIG. 23 illustrates a head-mounted display including a display device according to one or more embodiments;

FIG. 24 is a diagram illustrating a dashboard of an automobile and a center fascia including display devices according to one or more embodiments; and

FIG. 25 is a diagram illustrating a transparent display device including a display device according to one or more embodiments.

FIG. 26 is a block diagram of an electronic device according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

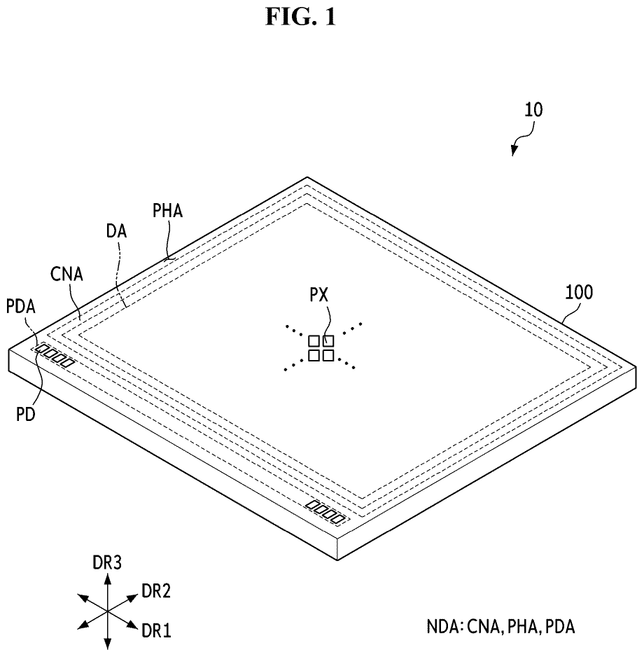

FIG. 1 is a perspective view illustrating a display device according to one or more embodiments.

Referring to FIG. 1, a display device 10 is a device for displaying a moving image or a still image, and may be used as a display screen for various electronic devices. For example, the display device 10 may be used as a display screen for various electronic devices, such as televisions, laptop computers, monitors, billboards and the Internet of Things (IOT), as well as portable electronic devices, such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs). Additionally, the display device 10 may be applied to other electronic devices, such as a virtual reality (VR) device, an augmented reality (AR) device, or the like. For example, the display device 10 may be included in at least one of the electronic devices described above, or may be included in electronic devices of other types.

In one or more embodiments, the display device 10 may be a light-emitting display device including light-emitting elements. For example, the display device 10 may be an organic light-emitting display including an organic light-emitting diode, a quantum dot light-emitting display including a quantum dot light-emitting layer, an inorganic light-emitting display including an inorganic semiconductor, or an ultra-small light-emitting display using an ultra-small light-emitting diode, such as a micro or nano light-emitting diode (micro LED or nano LED).

Hereinafter, embodiments in which the display device 10 is a light-emitting display device including a micro or nano light-emitting diode will be described. However, the type or size of the light-emitting element according to embodiments is not limited thereto.

The display device 10 may include a display panel 100 including a display area DA and a non-display area NDA. In one or more embodiments, the display panel 100 may have a quadrilateral planar shape, but is not limited thereto. For example, the display panel 100 may have a polygonal shape other than a quadrilateral shape, a circular shape, an elliptical shape, or another shape in plan view. In FIG. 1, a first direction DR1, a second direction DR2, and a third direction DR3 are indicated. In one or more embodiments, the first direction DR1, the second direction DR2, and the third direction DR3 may be the horizontal direction, the vertical direction, and the thickness direction of the display panel 100, respectively.

The display area DA may be an area in which pixels PX are located, and may be an area in which an image is displayed by the pixels PX. For example, the pixels PX and wires (or some of the wires) connected to the pixels PX may be located in the display area DA. In describing embodiments, the term “connect” may include electrical connection and/or physical connection. Although FIG. 1 illustrates one or more embodiments in which the planar shape of the display area DA is quadrilateral, the shape of the display area DA is not limited thereto.

The pixels PX may have a quadrilateral planar shape, such as a rectangular shape or a rhombic shape, but the present disclosure is not limited thereto. For example, the pixels PX may have another polygonal shape, a circular shape, an elliptical shape, or another shape in plan view. When the display device 10 is a light-emitting display device, each of the pixels PX may include at least one light-emitting element.

The pixels PX may be connected to a driving circuit and a power supply unit through wires and/or pads PD formed in the display panel 100 to receive driving signals and driving voltages. For example, the pixels PX may receive scan signals (or clock signals), data signals (or digital data), a first driving voltage (e.g., high-potential pixel voltage or anode voltage), and a second driving voltage (e.g., low-potential pixel voltage or cathode voltage). The pixels PX may emit light in response to the driving signals and the driving voltages.

In one or more embodiments, at least a part of the driving circuit that supplies the driving signals to the pixels PX may be formed in the display panel 100, or may be located on the non-display area NDA of the display panel 100. In one or more other embodiments, the driving circuit may be located outside the display panel 100 and electrically connected to the plurality of pads PD located in the pad area PDA. In one or more embodiments, the power supply unit that supplies the driving voltages to the pixels PX may be located outside the display panel 100 (for example, circuit board electrically connected to the display panel 100), and may be electrically connected to the plurality of pads PD located in the pad area PDA. However, the positions of the driving circuit and the power supply unit, or the connection structure of each of the driving circuit and the power supply unit and the pixels PX, may vary according to embodiments.

In one or more embodiments, each of the pixels PX may include a light-emitting element and a pixel circuit electrically connected to the light-emitting element. The driving signals and the first driving voltage of the pixels PX may be applied to the pixel circuit of each of the pixels PX, and the second driving voltage may be applied to the light-emitting elements LE of the pixels PX through a common electrode that is commonly connected to the light-emitting elements LE. In describing the following embodiments, the second driving voltage applied to the light-emitting elements LE through the common electrode may be referred to as “common voltage.”

The non-display area NDA may be an area where an image is not displayed. The non-display area NDA may be located around the display area DA.

In one example, the non-display area NDA may be located at the edge of the display panel 100 to surround the display area DA (e.g., in plan view).

The non-display area NDA may include a pad area PDA and a peripheral area PHA. In one or more embodiments, the non-display area NDA may further include a common electrode connection area CNA (also referred to as “common voltage supply area”) located around the display area DA. Wires (or portions of the wires) connected to the pixels PX, and pads PD may be located in the non-display area NDA.

The common electrode connection area CNA may be located on at least one side of the display area DA. For example, the common electrode connection area CNA may be located directly around the display area DA to surround the display area DA (e.g., in plan view). A common electrode shared by the pixels PX may be located in the display area DA, and the common electrode may extend to the common electrode connection area CNA. The common electrode may be connected to a wire formed on a backplane substrate of the display panel 100 in the common electrode connection area CNA, and may be connected to at least one pad PD (e.g., a common voltage pad to which the common voltage is applied) located in the pad area PDA through the wire. The common voltage may be applied to the common electrode through the at least one pad PD. The common voltage may be one of an anode voltage or a cathode voltage applied to one end of the light-emitting element LE located in each of the pixels PX. In one or more embodiments, when the display panel 100 has a common-cathode structure, the common voltage may be a cathode voltage.

The pads PD may be located in the pad area PDA. In one or more embodiments, the pads PD may be connected to a circuit board through a conductive ball, a wire, or another conductive connection member. The driving signals and the driving voltages for driving the display panel 100 may be supplied from the circuit board to the display device 10 through the pads PD.

The pad area PDA may be located at one end (e.g., lower end) of the display panel 100. The pad area PDA may include the pads PD to be connected to an external circuit board. The pads PD may be electrically connected to the pixels PX through respective connection lines in the display panel 100. In one or more embodiments, when a driving circuit including at least one of a gate driver, a data driver, or a timing controller is located in the display panel 100 and/or on the non-display area NDA, at least some of the pads PD may be connected to the driving circuit, and may transmit the driving signals and the driving voltages of the driving circuit.

The peripheral area PHA may be the remaining area of the non-display area NDA except the pad area PDA and the common electrode connection area CNA. The peripheral area PHA may surround the display area DA, the common electrode connection area CNA, and the pad area PDA.

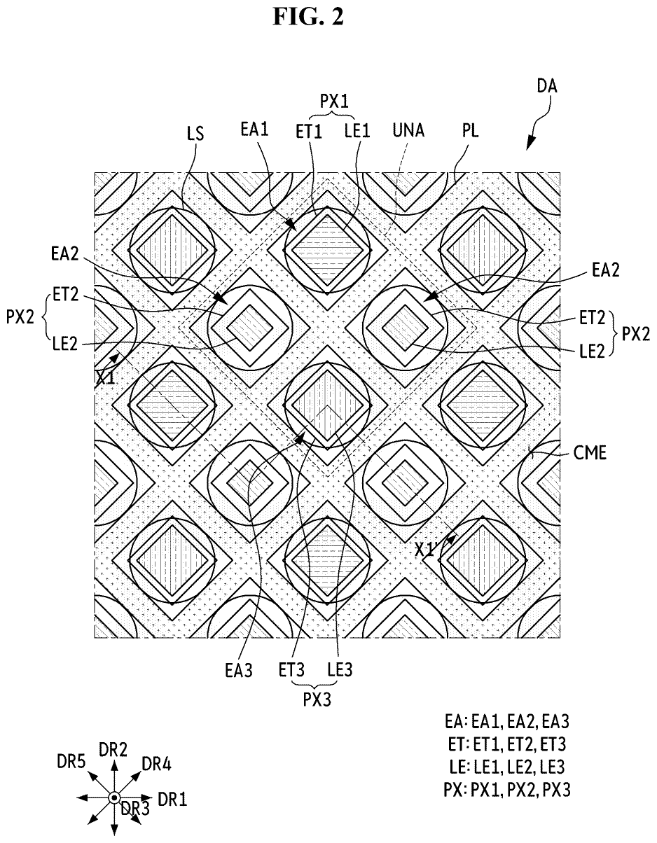

FIG. 2 is a plan view illustrating a display area of a display device according to one or more embodiments. For example, FIG. 2 schematically shows a part of the display area DA shown in FIG. 1.

Referring to FIGS. 1 and 2, the plurality of pixels PX may be located in the display area DA. The pixels PX may be arranged in the display area DA in a PENTILE™ shape (e.g., Diamond Pixel™ shape), a stripe shape, or another shape (PENTILE™ and Diamond Pixel™ being registered trademarks of Samsung Display Co., Ltd., Republic of Korea).

In one or more embodiments, the pixels PX may include first pixels PX1, second pixels PX2, and third pixels PX3 that emit light of a first color, light of a second color, and light of a third color, respectively. In one or more embodiments, the light of the first color, the light of the second color, and the light of the third color may be red light, green light, and blue light, respectively. For example, the first pixels PX1 may be red sub-pixels that emit red light, the second pixels PX2 may be green sub-pixels that emit green light, and the third pixels PX3 may be blue sub-pixels that emit blue light.

In one or more embodiments, a larger number of second pixels PX2 may be located in the display area DA compared to the first pixels PX1 and the third pixels PX3. For example, one first pixel PX1, two second pixels PX2, and one third pixel PX3 may be located in one unit area UNA of the display area DA. In one or more embodiments, the size of the second pixel PX2 (or the second light-emitting element LE2) may be smaller than the size of the first pixel PX1 (or the first light-emitting element LE1) and may be smaller than the size of the third pixel PX3 (or the third light-emitting element LE3), but the embodiments are not limited thereto. For example, in one or more other embodiments, the size of the second pixel PX2 (or the second light-emitting element LE2) may be substantially the same as or greater than the size of the first pixel PX1 (or the first light-emitting element LE1) and/or the third pixel PX3 (or the third light-emitting element LE3).

In one or more embodiments, the first pixels PX1 and the third pixels PX3 may be arranged alternately in the first direction DR1 and the second direction DR2. The first pixels PX1 and the second pixels PX2 may be arranged alternately in a fourth direction DR4 and a fifth direction DR5 between the first direction DR1 and the second direction DR2. The second pixels PX2 and the third pixels PX3 may be arranged alternately in the fourth direction DR4 and the fifth direction DR5. The second pixels PX2 may be arranged continuously or sequentially in the first direction DR1 and the second direction DR2.

The pixels PX of the display area DA and the arrangement structure of the pixels PX are not limited to the one or more embodiments corresponding to FIG. 2. For example, the type, number, ratio, size, arrangement structure of the pixels PX located in the display area DA, and/or the color of light emitted from the pixels PX, may vary according to embodiments.

The display area DA may include the emission areas EA of the pixels PX and the non-emission area surrounding the emission areas EA. The emission areas EA may correspond to light-transmitting areas through which light generated from the respective pixels PX may transmit. The non-emission area may be the remaining area of the display area DA except the emission areas EA of the pixels PX. The non-emission area may be located around the emission areas EA and between the emission areas EA.

The pixel PX may include an electrode ET (or a conductive layer) located in each emission area EA and the light-emitting element LE located on the electrode ET. For example, the first pixel PX1 may include a first electrode ET1 located in a first emission area EA1 and a first light-emitting element LE1 located on the first electrode ET1. The second pixel PX2 may include a second electrode ET2 located in a second emission area EA2 and a second light-emitting element LE2 located on the second electrode ET2. The third pixel PX3 may include a third electrode ET3 located in a third emission area EA3 and a third light-emitting element LE3 located on the third electrode ET3.

In one or more embodiments, the pixel PX may further include a pixel circuit electrically connected to the light-emitting element LE. In one or more embodiments, the pixel circuits of the pixels PX may be located or included in a backplane substrate coupled to the light-emitting elements LE of the pixels PX.

In one or more embodiments, the electrodes ET may be bonding electrodes for coupling the light-emitting elements LE to the backplane substrate. For example, the electrodes ET may be single-layer or multilayer bonding electrodes (e.g., conductive patterns including bonding metal) including a conductive material suitable for bonding, and the light-emitting elements ET may be bonded onto the backplane substrate by the electrodes ET. However, the type, structure, or material of the electrodes ET may vary according to embodiments.

The electrodes ET may have a size that is larger than the light-emitting elements LE in plan view, and may be located in an area that includes a region where the light-emitting elements LE are located and its surrounding region. However, the embodiments are not limited thereto. For example, the electrodes ET may have substantially the same size as the light-emitting elements LE in plan view.

The electrodes ET may have a shape corresponding to that of the light-emitting elements LE or may have a shape different from that of the light-emitting elements LE. For example, FIG. 2 illustrates one or more embodiments in which the light-emitting elements LE and the electrodes ET have a rhombic planar shape corresponding to each other, but the respective shapes of the light-emitting elements LE and the electrodes ET may be variously changed according to embodiments. For example, the light-emitting elements LE and the electrodes ET may each have a circular shape, a quadrilateral shape, a polygonal shape other than the quadrilateral shape, or another shape in plan view.

In one or more embodiments, the first electrode ET1, the second electrode ET2, and the third electrode ET3 may be formed of the same material and/or structure. In one or more other embodiments, at least two of the electrodes ET among the first electrode ET1, the second electrode ET2, and the third electrode ET3 may be formed of different materials and/or structures.

In one or more embodiments, the first light-emitting element LE1, the second light-emitting element LE2, and the third light-emitting element LE3 may emit light of different respective colors. For example, the first light-emitting element LE1 may be a red light-emitting element that emits light of the first color (e.g., red). The second light-emitting element LE2 may be a green light-emitting element that emits light of the second color (e.g., green). The third light-emitting element LE3 may be a blue light-emitting element that emits light of the third color (e.g., blue). However, the type or number of light-emitting elements LE located in each pixel PX may be variously changed according to embodiments.

In one or more other embodiments, the first light-emitting element LE1, the second light-emitting element LE2, and the third light-emitting element LE3 may emit light of the same color (e.g., blue light or white light). Further, color filters and/or light conversion patterns (e.g., wavelength conversion patterns including quantum dots) for converting the color or wavelength of light emitted from each light-emitting element LE may be located above at least one of the first light-emitting element LE1, the second light-emitting element LE2, or the third light-emitting element LE3.

In one or more embodiments, the light-emitting elements LE may be micro light-emitting diodes (micro LEDs) having a small size in the micrometer (μm) range. For example, each of the light-emitting elements LE may be a micro LED having a length (e.g., horizontal length) in the first direction DR1, a length (e.g., vertical length) in the second direction DR2, and a length (e.g., thickness or height) in the third direction DR3, which are several micrometers to several hundred micrometers, respectively. In one or more embodiments, each of the length of the light-emitting element LE in the first direction DR1, the length in the second direction DR2, and the length in the third direction DR3 may be about 100 μm or less, but the embodiments are not limited thereto.

A common electrode CME may be located on the light-emitting elements ED of the pixels PX. In one or more embodiments, the common electrode CME may be located in the entire display area DA, and the pixels PX may share the common electrode CME.

A power line PL (e.g., common voltage line) connected to the common electrode CME may be further located in the display area DA. In one or more embodiments, the power line PL may include openings corresponding to the emission areas EA of the pixels PX, and may be a mesh-shaped line located in the non-emission area surrounding the emission areas EA.

In one or more embodiments, an optical structure (e.g., a microlens array including microlenses LS arranged in a shape corresponding to the pixels PX) for increasing the light emission efficiency of the pixels PX may be further located on the common electrode CME. For example, the lens LS covering each of the light-emitting elements LE of the pixels PX may be located on the common electrode CME.

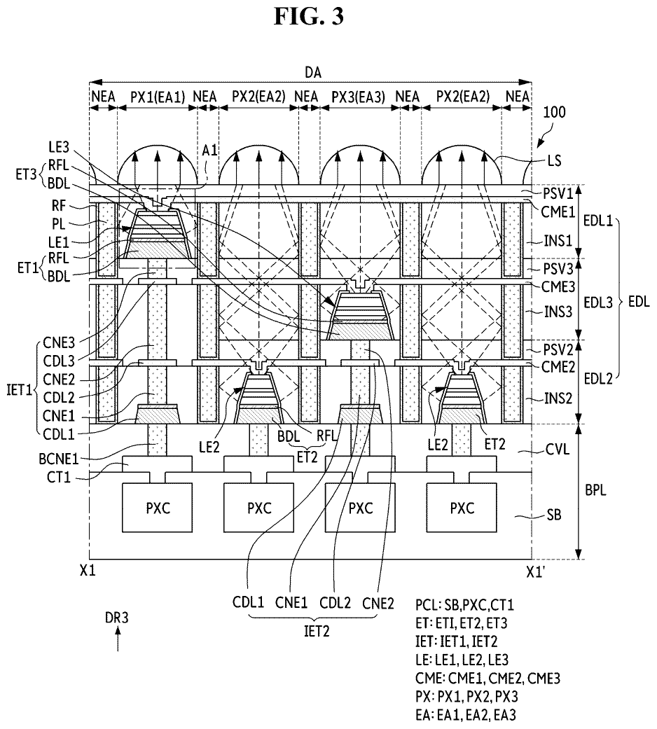

FIG. 3 is a cross-sectional view illustrating a display panel according to one or more embodiments. For example, FIG. 3 shows one or more embodiments of a cross-section of the display panel 100 taken along the line X1-X1′ of FIG. 2, which is a schematic cross-section of the first pixel PX1, the second pixels PX2, and the third pixel PX3 located in a portion of the display area DA.

FIG. 3 illustrates one or more embodiments in which the display device 10 includes the display panel 100 having a light-emitting diode on silicon (LEDoS) structure in which light-emitting diodes are located as the light-emitting elements LE, on a semiconductor circuit board PCL formed by a semiconductor process using a silicon wafer. However, the structure or type of the display device or the electronic device to which embodiments may be applied is not limited thereto. For example, the embodiments may be applied to display devices of other types or structures, or may be applied to electronic devices of other types or structures, such as lighting devices.

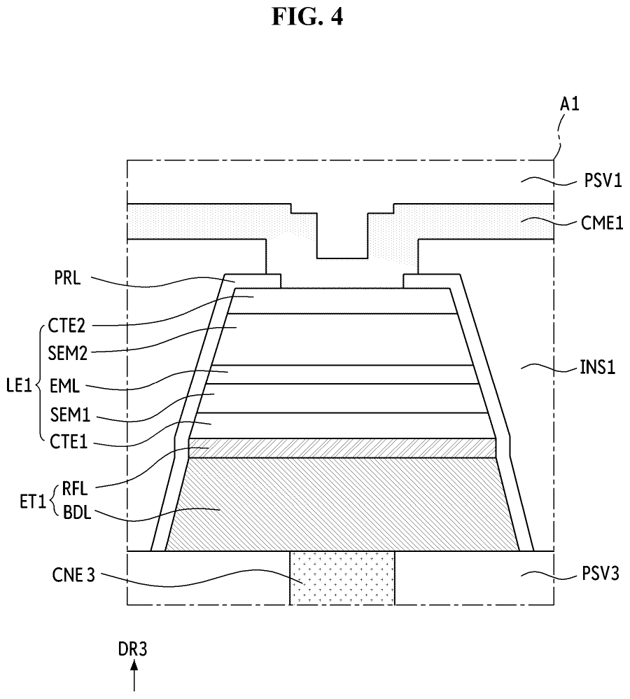

FIG. 4 is a cross-sectional view showing a light-emitting element according to one or more embodiments. For example, FIG. 4 shows a cross-section of the first light-emitting element LE1 located in area A1 of FIG. 3. In one or more embodiments, the first light-emitting element LE1, the second light-emitting element LE2, and the third light-emitting element LE3 may have substantially the same or similar cross-sectional structure.

Referring to FIGS. 1 to 4, the display panel 100 may include a backplane substrate BPL, and a light-emitting element layer EDL located on the backplane substrate BPL (as used herein, “located on” may mean “above”). In one or more embodiments, the display panel 100 may further include an optical structure (e.g., a microlens array including the lenses LS) located on the light-emitting element layer EDL.

The backplane substrate BPL may include a semiconductor circuit board PCL (or thin film transistor substrate), and connection electrodes BCNE1 and a cover layer CVL that are located on the semiconductor circuit board PCL. The semiconductor circuit board PCL and the backplane substrate BPL including the same may include the display area DA where pixel circuits PXC of the pixels PX are formed. The semiconductor circuit board PCL may further include the non-display area NDA of FIG. 1. For example, the semiconductor circuit board PCL may further include the pads PD located in the non-display area NDA, and wires connected to the pads PD. The backplane substrate BPL may also be referred to as “backplane layer” or “lower substrate.”

The semiconductor circuit board PCL may include a base substrate SB, the pixel circuits PXC located or formed on the base substrate SB, and first contact terminals CT1 (or pixel electrodes) electrically connected to the respective pixel circuits PXC. The semiconductor circuit board PCL may further include wires electrically connected to the pixels PX and the pads PD.

In one or more embodiments, the semiconductor circuit board PCL may be formed through a semiconductor process using a silicon wafer. For example, the base substrate SB may be a silicon wafer. In one or more embodiments, the base substrate SB may be made of monocrystalline silicon.

The pixel circuits PXC may be located on the semiconductor circuit board PCL to correspond to the respective pixel areas where the respective pixels PX are located. In one or more embodiments, each of the pixel circuits PXC may include a complementary metal oxide semiconductor (CMOS) circuit formed using a semiconductor process. In one or more embodiments, each of the pixel circuits PXC may include at least one transistor and at least one capacitor formed through a semiconductor process. FIG. 3 illustrates schematic positions of the pixel circuits PXC included in the first pixel PX1, the second pixels PX2, and the third pixel PX3, as an example of elements located in the semiconductor circuit board PCL.

The first contact terminals CT1 may be located on the pixel circuits PXC, respectively. The first contact terminals CT1 may be connected to the pixel circuits PXC, respectively. For example, the pixel circuit PXC of each of the pixels PX may be electrically connected to the first contact terminals CT1 of the corresponding pixel PX. The first contact terminals CT1 may receive a first driving voltage (e.g., first pixel voltage or anode voltage) from the respective pixel circuits PXC.

In one or more embodiments, the first contact terminals CT1 may be formed integrally with the respective pixel circuits PXC. For example, the first contact terminals CT1 may be exposed electrodes, conductive patterns, or wires protruding from the top surfaces of the respective pixel circuits PXC.

The first contact terminals CT1 may include a conductive material. For example, the first contact terminals CT1 may include, but not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof.

The first contact terminals CT1 may be electrically connected to the respective light-emitting elements LE through the respective connection electrodes BCNE1 and the respective electrodes ET. For example, the first contact terminal CT1 of each pixel PX may be electrically connected to the light-emitting element LE on the electrode ET through the connection electrode BCNE1 of the corresponding pixel PX and the electrode ET located on the connection electrode BCNE1. In one or more embodiments, the electrode ET and the light-emitting element LE of at least one pixel PX may be electrically connected to the connection electrode BCNE1 of the backplane substrate BPL through an intermediate electrode IET.

The cover layer CVL may be located on the pixel circuits PXC and the first contact terminals CT1. The cover layer CVL may cover the semiconductor circuit board PCL including the base substrate SB, the pixel circuits PXC, and the first contact terminals CT1. The cover layer CVL may also be referred to as “lower insulating layer,” “lower passivation layer,” or “protective layer.”

The cover layer CVL may include, or may define, openings (e.g., contact holes or via holes) that partially expose the first contact terminals CT1. The openings may be filled with the connection electrodes BCNE1. For example, the cover layer CVL may surround the connection electrodes BCNE1.

The cover layer CVL may include an insulating material, and may have a single-layer or multilayer structure. In one or more embodiments, the cover layer CVL may include an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or another inorganic insulating material), but is not limited thereto.

The connection electrodes BCNE1 may connect the electrodes ET of the light-emitting element layer EDL to the semiconductor circuit board PCL. For example, the connection electrodes BCNE1 may be electrically connected between the first electrode ET1, the second electrode ET2, or the third electrode ET3 of each of the pixels PX and the first contact terminal CT1 (or the pixel circuit PXC).

In one or more embodiments, the connection electrodes BCNE1 may include a conductive material (e.g., metal). For example, the connection electrodes BCNE1 may include at least one of gold (Au), copper (Cu), tin (Sn), titanium (Ti), aluminum (Al), or silver (Ag).

The light-emitting element layer EDL may include the electrodes ET and the light-emitting elements LE of the respective pixels PX. Further, the light-emitting element layer EDL may include the power lines PL and insulating layers located around the electrodes ET and the light-emitting elements LE, and the common electrode CME located on the light-emitting elements LE.

In one or more embodiments, the light-emitting element layer EDL may have a 3-color staggered structure. For example, the light-emitting elements LE that respectively emit light of the first color, light of the second color, and light of the third color may be located in different respective layers in the light-emitting element layer EDL, and may be located in different emission areas EA in plan view.

For example, the light-emitting element layer EDL may include a first light-emitting element layer EDL1 in which the first light-emitting element LE1 of each of the first pixels PX1 is located, a second light-emitting element layer EDL2 in which the second light-emitting element LE2 of each of the second pixels PX2 is located, and a third light-emitting element layer EDL3 in which the third light-emitting element LE3 of each of the third pixels PX3 is located. When the first light-emitting element LE1, the second light-emitting element LE2, and the third light-emitting element LE3 are located in different respective layers, the light-emitting elements LE of different colors or types may be located or bonded more suitably on the backplane substrate BPL. The first light-emitting element LE1, the second light-emitting element LE2, and the third light-emitting element LE3 may be located in the first emission area EA1, the second emission area EA2, and the third emission area EA3, respectively. The first emission area EA1, the second emission area EA2, and the third emission area EA3 may be spaced apart from each other in plan view and may be surrounded by the non-emission area NEA. Accordingly, optical interference between the pixels PX may be prevented or reduced.

In one or more embodiments, among the first light-emitting element layer EDL1, the second light-emitting element layer EDL2, and the third light-emitting element layer EDL3, the first light-emitting element layer EDL1 may be located at the uppermost portion, the second light-emitting element layer EDL2 may be located at the lowermost portion, and the third light-emitting element layer EDL3 may be located between the first light-emitting element layer EDL1 and the second light-emitting element layer EDL2. For example, the second light-emitting element layer EDL2, the third light-emitting element layer EDL3, and the first light-emitting element layer EDL1 may be sequentially located on the backplane substrate BPL along the third direction DR3. However, the arrangement order of the first light-emitting element layer EDL1, the second light-emitting element layer EDL2, and the third light-emitting element layer EDL3 may be variously changed according to embodiments. For example, the first light-emitting element layer EDL1, the second light-emitting element layer EDL2, and the third light-emitting element layer EDL3 may be sequentially arranged on the backplane substrate BPL according to one of the possible combinations related to the arrangement order thereof.

The first light-emitting element layer EDL1 may include the first electrode ET1 and the first light-emitting element LE1 of each of the first pixels PX1, and a first common electrode CME1 located on the first light-emitting element LE1. In one or more embodiments, the first light-emitting element layer EDL1 may further include a part (e.g., upper part) of the power line PL, and a reflective film RF surrounding a part of the power line PL (e.g., surrounding in plan view). The first light-emitting element layer EDL1 may further include a first insulating layer INS1 filled in a space between the lower layer thereof (e.g., the third light-emitting element layer EDL3) and the first common electrode CME1, and a first passivation layer PSV1 covering the first common electrode CME1.

The second light-emitting element layer EDL2 may include the second electrode ET2 and the second light-emitting element LE2 of each of the second pixels PX2, and a second common electrode CME2 located on the second light-emitting element LE2. In one or more embodiments, the second light-emitting element layer EDL2 may further include a first conductive layer CDL1, a first connection electrode CNE1, and a second conductive layer CDL2 of a first intermediate electrode IET1 located in each first pixel PX1, may further include a part of a second connection electrode CNE2 of the first intermediate electrode IET1, a first conductive layer CDL1, a first connection electrode CNE1, a second conductive layer CDL2, and a second connection electrode CNE2 of a second intermediate electrode IET2 located in each third pixel PX3, may further include a part (e.g., lower part) of the power line PL, and may further include the reflective film RF covering a part of the power line PL. The second light-emitting element layer EDL2 may further include a second insulating layer INS2 filled in a space between the lower layer thereof (e.g., the backplane substrate BPL) and the second common electrode CME2, and a second passivation layer PSV2 covering the second common electrode CME2.

The third light-emitting element layer EDL3 may include the third electrode ET3 and the third light-emitting element LE3 of each of the third pixels PX3, and a third common electrode CME3 located on the third light-emitting element LE3. In one or more embodiments, the third light-emitting element layer EDL3 may further include a part of the second connection electrode CNE2 of the first intermediate electrode IET1 located in each first pixel PX1, may further include a third conductive layer CDL3 and a third connection electrode CNE3 of the first intermediate electrode IET1, and also may include a part (e.g., intermediate part) of the power line PL, and the reflective film RF covering a part of the power line PL. The third light-emitting element layer EDL3 may further include a third insulating layer INS3 filled in a space between the lower layer thereof (e.g., the second light-emitting element layer EDL2) and the third common electrode CME3, and a third passivation layer PSV3 covering the third common electrode CME3.

The first electrode ET1, the second electrode ET2, and the third electrode ET3 may be located on the respective connection electrodes BCNE1 provided in the respective pixels PX. The first electrode ET1, the second electrode ET2, and the third electrode ET3 may be electrically connected to the respective pixel circuits PXC through the respective connection electrodes BCNE1.

In one or more embodiments, the first intermediate electrode IET1 may be located on the connection electrode BCNE1 of the first pixel PX1, and the first electrode ET1 may be located on the first intermediate electrode IET1. The first electrode ET1 may be electrically connected to the connection electrode BCNE1 of the first pixel PX1 through the first intermediate electrode IET1.

The first intermediate electrode IET1 may be connected between the backplane substrate BPL and the first electrode ET1. The first intermediate electrode IET1 may include the first conductive layer CDL1, the first connection electrode CNE1, the second conductive layer CDL2, the second connection electrode CNE2, the third conductive layer CDL3, and the third connection electrode CNE3 that are sequentially connected between the backplane substrate BPL and the first electrode ET1.

In one or more embodiments, the second electrode ET2 may be directly located on (e.g., may contact) the connection electrode BCNE1 of the second pixel PX2. The second electrode ET2 may be electrically connected to the connection electrode BCNE1 of the second pixel PX2.

In one or more embodiments, the second intermediate electrode IET2 may be located on the connection electrode BCNE1 of the third pixel PX3, and the third electrode ET3 may be located on the second intermediate electrode IET2. The third electrode ET3 may be electrically connected to the connection electrode BCNE1 of the third pixel PX3 through the second intermediate electrode IET2.

The second intermediate electrode IET2 may be connected between the backplane substrate BPL and the third electrode ET3. The second intermediate electrode IET2 may include the first conductive layer CDL1, the first connection electrode CNE1, the second conductive layer CDL2, and the second connection electrode CNE2 that are sequentially located or connected between the backplane substrate BPL and the third electrode ET3.

The electrodes ET may physically and/or electrically couple the backplane substrate BPL to the light-emitting elements LE. In one or more embodiments, the electrodes ET may be bonding electrodes (or bonding pads) for stably bonding the light-emitting elements LE on the backplane substrate BPL. For example, the first electrode ET1 may be the bonding electrode of the first pixel PX1, the second electrode ET2 may be the bonding electrode of the second pixel PX2, and the third electrode ET3 may be the bonding electrode of the third pixel PX3.

However, the types of the electrodes ET are not limited thereto, and the types, structures, and/or materials of the electrodes ET may vary according to the coupling structure, the coupling method, or the like between the backplane substrate BPL and the light-emitting elements LE. Hereinafter, one or more embodiments in which the electrodes ET are bonding electrodes is described.

Each of the electrodes ET may be constituted with a single layer or multiple layers including the bonding layer BDL (also referred to as “bonding metal layer”). For example, each of the electrodes ET may include the bonding layer BDL, and a reflective layer RFL located on the bonding layer BDL.

The bonding layer BDL of the first electrode ET1 may be located on the third light-emitting element layer EDL3. The bonding layer BDL of the second electrode ET2 may be located on the backplane substrate BPL. The bonding layer BDL of the third electrode ET3 may be located on the second light-emitting element layer EDL2.

In one or more embodiments, the bonding layer BDL may include a conductive material suitable for the bonding process. For example, the bonding layer BDL may include a metal or metal alloy with excellent electrical and thermal conductivity, or may include a transparent conductive material that allows a bonding process. Examples of metals or metal alloys that may be included in the bonding layer BDL include eutectic metals, such as gold (Au)-tin (Sn) alloy, titanium (Ti), zirconium (Zr), nickel (Ni), or chromium (Cr). Examples of transparent conductive materials that may be included in the bonding layer BDL may include indium tin oxide (ITO), zinc oxide (ZnO), or the like. The bonding layer BDL may also be formed of other conductive materials. The bonding layer BDL may have a thickness (e.g., a thickness of approximately several hundred nanometers) that is sufficient to appropriately or suitably perform a bonding process.

The reflective layer RFL may be located on the bonding layer BDL. In one or more embodiments, the reflective layer RFL may include a conductive material (e.g., metal) with high light reflectivity. For example, the reflective layer RFL may include aluminum (Al) or may include other metals (e.g., molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr)) with high light reflectivity. In one or more other embodiments, the reflective layer RFL may include a plurality of transparent conductive layers that may function as distributed Bragg reflectors (DBR).

In one or more embodiments, the reflective layer RFL may completely cover the bottom surface of each of the light-emitting elements LE. Accordingly, the light that has traveled downward from each of the light-emitting elements LE may be effectively reflected, so that the light efficiency of the pixel PX may be increased.

In one or more embodiments, each of the electrodes ET may further include a barrier layer covering at least one surface of the bonding layer BDL or the reflective layer RFL. For example, each of the electrodes ET may further include at least one of a first barrier layer covering a bottom surface of the bonding layer BDL, a second barrier layer covering a top surface of the bonding layer BDL and a bottom surface of the reflective layer RFL, or a third barrier layer covering a top surface of the reflective layer RFL.

The barrier layer may include a material suitable for reducing or preventing diffusion (e.g., reducing or preventing inter-metal diffusion). Additionally, the barrier layer may be formed of a material and/or thickness capable of ensuring conductivity of each of the electrodes ET. In one or more embodiments, the barrier layer may be formed of a thin film including a material having a high inter-metal diffusion reduction/prevention effect, for example, titanium (Ti), titanium nitride (TiN), nickel (Ni), or another diffusion reduction/prevention material.

The light-emitting elements LE may be located on the electrodes ET, respectively. For example, the first light-emitting element LE1, the second light-emitting element LE2, and the third light-emitting element LE3 may be located on the first electrode ET1, the second electrode ET2, and the third electrode ET3, respectively.

Although FIG. 3 illustrates the display panel 100 having a structure in which the electrodes ET are located on the backplane substrate BPL, and in which the light-emitting elements LE are coupled to the backplane substrate BPL by the electrodes ET, the structure of the display panel 100 according to embodiments is not limited thereto. For example, instead of using a bonding method utilizing the bonding layer BDL, the light-emitting elements LE may be appropriately located or bonded on the backplane substrate BPL by utilizing an adhesive layer, connection electrodes, and/or wires.

Each of the light-emitting elements LE may include a first semiconductor layer SEM1, a light-emitting layer EML, and a second semiconductor layer SEM2 sequentially located on each electrode ET. In one or more embodiments, each of the light-emitting elements LE may further include a first contact electrode CTE1 covering one surface (e.g., bottom surface) of the first semiconductor layer SEM1, and may further include a second contact electrode CTE2 covering one surface (e.g., top surface) of the second semiconductor layer SEM2. For example, the first contact electrode CTE1, the first semiconductor layer SEM1, the light-emitting layer EML, the second semiconductor layer SEM2, and the second contact electrode CTE2 may be sequentially located on each electrode ET along the third direction DR3. In one or more other embodiments, each of the light-emitting elements LE may omit at least one of the first contact electrode CTE1 or the second contact electrode CTE2.

The first contact electrode CTE1 may be located on the first electrode ET1, the second electrode ET2, or the third electrode ET3 of each of the pixels PX. The first contact electrode CTE1 may be located on one surface (e.g., bottom surface) of the first semiconductor layer SEM1 included in the light-emitting element LE. The first contact electrode CTE1 may protect the first semiconductor layer SEM1, and may smoothly connect the light-emitting element LE to each electrode ET.

The first contact electrode CTE1 may include metal, metal oxide, or other conductive materials. In one or more embodiments, the first contact electrode CTE1 may include a transparent conductive material (e.g., indium tin oxide (ITO), indium zinc oxide (IZO), or another transparent conductive material), but is not limited thereto.

The first semiconductor layer SEM1, the light-emitting layer EML, and the second semiconductor layer SEM2 may be formed from a semiconductor thin film layer (semiconductor epitaxial stack) or epi-layers formed by epitaxial growth on a semiconductor substrate.

The first semiconductor layer SEM1 may include a semiconductor material doped with a first conductivity type dopant. For example, the first semiconductor layer SEM1 may be a semiconductor layer of a first conductivity type that includes a nitride-based semiconductor material, a phosphide-based semiconductor material, or another semiconductor material, and that further includes a dopant of a first conductivity type. In one or more embodiments, the first semiconductor layer SEM1 may be a p-type semiconductor layer (e.g., p-GaN) doped with a p-type dopant, such as Mg, Zn, Ca, Se, and Ba.

The light-emitting layer EML may be located on the first semiconductor layer SEM1. For example, the light-emitting layer EML may be located between the first semiconductor layer SEM1 and the second semiconductor layer SEM2. The light-emitting layer EML may emit light by recombination of electron-hole pairs generated in response to an electrical signal applied through the first semiconductor layer SEM1 and the second semiconductor layer SEM2.

The light-emitting layer EML may include a nitride-based semiconductor material, a phosphide-based semiconductor material, or another semiconductor material, and may have a single-or multiple-quantum well structure. In one or more embodiments, the light-emitting layer EML may have a multiple-quantum well structure including a quantum well layer including InGaN and a barrier layer including GaN, AlGaN, or GaAlN, but is not limited thereto. In one or more embodiments, when the light-emitting layer EML includes InGaN, the color of light emitted from the light-emitting layer EML may be adjusted or changed by adjusting the content of indium (In).

The light-emitting layer EML may emit light in a visible light wavelength band, for example, light in a wavelength band of approximately 400 nm to approximately 900 nm. For example, the light-emitting layer EML may emit blue light having a peak wavelength within a range of approximately 440 nm to approximately 480 nm, green light having a peak wavelength within a range of approximately 510 nm to approximately 550 nm, or red light having a peak wavelength within a range of approximately 610 nm to approximately 650 nm. For example, the light-emitting layer EML of the first light-emitting element LE1 may emit red light, the light-emitting layer EML of the second light-emitting element LE2 may emit green light, and the light-emitting layer EML of the third light-emitting element LE3 may emit blue light. The light-emitting layer EML may emit light whose color or wavelength band is different from the color or the wavelength band described above.

The second semiconductor layer SEM2 may include a semiconductor material doped with a second conductivity type dopant. For example, the second semiconductor layer SEM2 may be a semiconductor layer of a second conductivity type that includes a nitride-based semiconductor material, a phosphide-based semiconductor material, or another semiconductor material and further includes a dopant of a second conductivity type. In one or more embodiments, the second semiconductor layer SEM2 may be an n-type semiconductor layer (e.g., n-GaN) doped with an n-type dopant, such as Si, Ge, and Sn.

The second contact electrode CTE2 may be located on one surface (e.g., top surface) of the second semiconductor layer SEM2. The second contact electrode CTE2 may protect the second semiconductor layer SEM2, and may smoothly connect the light-emitting element LE to the common electrode CME (e.g., the first common electrode CME1, the second common electrode CME2, or the third common electrode CME3).

The second contact electrode CTE2 may include metal, metal oxide, or other conductive materials. In one or more embodiments, the second contact electrode CTE2 may be formed of a transparent electrode layer including a transparent conductive material (e.g., indium tin oxide (ITO), indium zinc oxide (IZO), or another transparent conductive material). Light generated in the light-emitting element LE may pass through the second contact electrode CTE2 and may be emitted to the upper side of the light-emitting element LE.

In one or more embodiments, the light-emitting elements LE may be formed by etching the semiconductor thin film layer or the epi-layers, which are grown on a semiconductor substrate, on the semiconductor substrate, and the light-emitting elements LE may be located or bonded on the respective electrodes ET by using at least one transfer substrate. In one or more other embodiments, a semiconductor thin film layer or epi-layers grown on the semiconductor substrate may be located or bonded on the backplane substrate BPL by a wafer-to-wafer bonding process or the like, and then may be etched to form the light-emitting elements LE. The electrodes ET may be etched and separated into individual patterns after the light-emitting elements LE are formed or located on the backplane substrate BPL, or may be formed and separated into individual patterns before the light-emitting elements LE are formed or located on the backplane substrate BPL.

The first contact electrode CTE1 and the second contact electrode CTE2 may be formed or etched together with the light-emitting element LE, or may be formed or etched separately from the light-emitting element LE.

In one or more embodiments, the light-emitting element layer EDL may further include a protective film PRL that surrounds the light-emitting elements LE. For example, each of the first light-emitting element layer EDL1, the second light-emitting element layer EDL2, and the third light-emitting element layer EDL3 may include the protective film PRL that surrounds at least the light-emitting elements LE.

The protective film PRL may surround the side surfaces of the light-emitting elements LE. In one or more embodiments, the protective film PRL may further surround the side surfaces of the electrodes ET. For example, the protective film PRL may surround the side surfaces of the light-emitting elements LE and the electrodes ET, and may be individually located in each pixel area. In one or more other embodiments, the protective film PRL may be located in the entire display area DA to surround the side surfaces of the electrodes ET and the light-emitting elements LE.

The protective film PRL may include an opening that exposes a part, e.g., top surface, of each of the light-emitting elements LE. For example, the protective film PRL may include an opening that exposes a part of the top surface of each of the light-emitting elements LE. In the opened portion of the protective film PRL, the light-emitting element LE may be connected to the common electrode CME.

The protective film PRL may include at least one insulating material selected from silicon oxide (SiOₓ), silicon nitride (SiNₓ), aluminum oxide (AlₓO_{y}), titanium oxide (TiₓO_{y}), and hafnium oxide (HfOₓ), or another insulating material. The protective film PRL may protect the light-emitting element LE, and may improve the electrical stability of the light-emitting element LE.

The first common electrode CME1, the second common electrode CME2, and the third common electrode CME3 may be located on the first light-emitting element LE1, the second light-emitting element LE2, and the third light-emitting element LE3, respectively. The first common electrode CME1 may be located in the entire display area DA, and may be a common layer shared by the first pixels PX1. The first common electrode CME1 may be electrically connected to the second contact electrodes CTE2 (or the second semiconductor layers SEM2) of the first light-emitting elements LE1. The second common electrode CME2 may be located in the entire display area DA, and may be a common layer shared by the second pixels PX2. The second common electrode CME2 may be electrically connected to the second contact electrodes CTE2 (or the second semiconductor layers SEM2) of the second light-emitting elements LE2. The third common electrode CME3 may be located in the entire display area DA, and may be a common layer shared by the third pixels PX3. The third common electrode CME3 may be electrically connected to the second contact electrodes CTE2 (or the second semiconductor layers SEM2) of the third light-emitting elements LE3. Each of the second common electrode CME2 and the third common electrode CME3 may be partially opened around the intermediate electrode IET (for example, at the circumference of the intermediate electrode IET). Accordingly, each of the second common electrode CME2 and the third common electrode CME3 may be insulated from the intermediate electrode IET.

In one or more embodiments, a part of the first common electrode CME1, the second common electrode CME2, and the third common electrode CME3 may be located on the first light-emitting element LE1, the second light-emitting element LE2, and the third light-emitting element LE3, respectively, and another part of the first common electrode CME1, the second common electrode CME2, and the third common electrode CME3 may be located on the first insulating layer INS1, the second insulating layer INS2, and the third insulating layer INS3, respectively. The first common electrode CME1, the second common electrode CME2, and the third common electrode CME3 may be electrically connected to the first light-emitting element LE1, the second light-emitting element LE2, and the third light-emitting element LE3 through openings formed in the first insulating layer INS1, the second insulating layer INS2, and the third insulating layer INS3, respectively. The first common electrode CME1, the second common electrode CME2, and the third common electrode CME3 may be electrically connected to each other through the power line PL. The first common electrode CME1, the second common electrode CME2, and the third common electrode CME3 may constitute one common electrode CME to which the same common voltage is applied.

Each of the first common electrode CME1, the second common electrode CME2, and the third common electrode CME3 may include a transparent conductive material that may transmit light. For example, each of the first common electrode CME1, the second common electrode CME2, and the third common electrode CME3 may be formed of indium tin oxide (ITO), indium zinc oxide (IZO), or another transparent conductive material.

The power line PL may be located in the non-emission area NEA surrounding the emission areas EA. The power line PL may surround the light-emitting elements LE located in the emission areas EA. In one or more embodiments, the power line PL may penetrate a plurality of insulating layers (e.g., the first insulating layer INS1, the second insulating layer INS2, the third insulating layer INS3, the second passivation layer PSV2, and the third passivation layer PSV3) located in the first light-emitting element layer EDL1, the second light-emitting element layer EDL2, and the third light-emitting element layer EDL3, and may be electrically connected to the first common electrode CME1, the second common electrode CME2, and the third common electrode CME3.

The power line PL may include a conductive material (for example, metal). For example, the power line PL may include at least one of gold (Au), copper (Cu), tin (Sn), titanium (Ti), aluminum (Al), or silver (Ag).

The reflective film RF may cover the side surface of the power line PL. In one or more embodiments, the reflective film RF may further cover the bottom surface of the power line PL. In plan view, the reflective film RF may surround the emission areas EA where the respective light-emitting elements LE are located. Further, the reflective film RF may face the side surfaces of the light-emitting elements LE.

In one or more embodiments, the reflective film RF may include metal with high reflectivity, such as aluminum (Al). However, the embodiments are not limited thereto. For example, the reflective film RF may be formed as a multilayer distributed Bragg reflector. When the reflective film RF has an insulating property, the reflective film RF may be located only on the side surface of the power line PL.

The reflective film RF may reflect and recycle light generated from each of the light-emitting elements LE and directed in a lateral direction, or the like. For example, light generated from each of the light-emitting elements LE and directed in a lateral direction may be reflected once or multiple times by the reflective film RF as indicated by dotted lines in FIG. 3, and may be emitted to the upper side of each of the pixels PX through various paths. The light emitted to the upper side of the pixels PX may be emitted to the upper side of the display panel 100 through the lens LS. In FIG. 3, the approximate path of light emitted to the upper side of the display panel 100 through the lens LS is illustrated by solid arrows. Most of the light that has passed through the lens LS may be directed mainly toward the front side of the display panel 100, and some of the light may also be directed in the lateral direction within a corresponding viewing angle range.

The light emission rate of light generated from each of the light-emitting elements LE may be increased by the reflective film RF. Accordingly, the light efficiency of the pixels PX may be improved.

The first conductive layer CDL1 of each of the first intermediate electrode IET1 and the second intermediate electrode IET2 may be located in the same layer as the second electrode ET2. The first conductive layer CDL1 and the second electrode ET2 of each of the first intermediate electrode IET1 and the second intermediate electrode IET2 may be spaced apart and separated from each other. In one or more embodiments, the first conductive layer CDL1 and the second electrode ET2 of each of the first intermediate electrode IET1 and the second intermediate electrode IET2 may be formed concurrently or substantially simultaneously using the same conductive material. In this case, the first conductive layer CDL1 and the second electrode ET2 of each of the first intermediate electrode IET1 and the second intermediate electrode IET2 may include the same conductive material, and may have the same cross-sectional structure.

The first connection electrode CNE1 of each of the first intermediate electrode IET1 and the second intermediate electrode IET2 may penetrate the second insulating layer INS2. The first connection electrode CNE1 of the first intermediate electrode IET1 may connect the first conductive layer CDL1 and the second conductive layer CDL2 of the first intermediate electrode IET1. The first connection electrode CNE1 of the second intermediate electrode IET2 may connect the first conductive layer CDL1 and the second conductive layer CDL2 of the second intermediate electrode IET2. In one or more embodiments, the first connection electrode CNE1 of each of the first intermediate electrode IET1 and the second intermediate electrode IET2 and a part (e.g., lower part) of the power line PL may be formed concurrently or substantially simultaneously using the same conductive material. In this case, the first connection electrode CNE1 of each of the first intermediate electrode IET1 and the second intermediate electrode IET2 and a part of the power line PL may include the same conductive material.

The second conductive layer CDL2 of each of the first intermediate electrode IET1 and the second intermediate electrode IET2 may be located in the same layer as the second common electrode CME2. The second conductive layer CDL2 and the second common electrode CME2 of each of the first intermediate electrode IET1 and the second intermediate electrode IET2 may be spaced apart and separated from each other. In one or more embodiments, the second conductive layer CDL2 and the second common electrode CME2 of each of the first intermediate electrode IET1 and the second intermediate electrode IET2 may be formed concurrently or substantially simultaneously using the same conductive material. In this case, the second conductive layer CDL2 and the second common electrode CME2 of each of the first intermediate electrode IET1 and the second intermediate electrode IET2 may include the same conductive material.

The second connection electrode CNE2 of the first intermediate electrode IET1 may penetrate the second passivation layer PSV2 and the third insulating layer INS3, and the second connection electrode CNE2 of the second intermediate electrode IET2 may penetrate the second passivation layer PSV2. The second connection electrode CNE2 of the first intermediate electrode IET1 may connect the second conductive layer CDL2 and the third conductive layer CDL3 of the first intermediate electrode IET1. The second connection electrode CNE2 of the second intermediate electrode IET2 may connect the second conductive layer CDL2 of the second intermediate electrode IET2 to the third electrode ET3. In one or more embodiments, the second connection electrode CNE2 of each of the first intermediate electrode IET1 and the second intermediate electrode IET2 and a part (e.g., intermediate part) of the power line PL may be formed concurrently or substantially simultaneously using the same conductive material. In this case, the second connection electrode CNE2 of each of the first intermediate electrode IET1 and the second intermediate electrode IET2 and a part of the power line PL may include the same conductive material.

The third conductive layer CDL3 of the first intermediate electrode IET1 may be located in the same layer as the third common electrode CME3. The third conductive layer CDL3 of the first intermediate electrode IET1 and the third common electrode CME3 may be spaced apart and separated from each other. In one or more embodiments, the third conductive layer CDL3 of the first intermediate electrode IET1 and the third common electrode CME3 may be formed concurrently or substantially simultaneously using the same conductive material. In this case, the third conductive layer CDL3 of the first intermediate electrode IET1 and the third common electrode CME3 may include the same conductive material.

The third connection electrode CNE3 of the first intermediate electrode IET1 may penetrate the third passivation layer PSV3. The third connection electrode CNE3 of the first intermediate electrode IET1 may connect the third conductive layer CDL3 of the first intermediate electrode IET1 to the first electrode ET1. In one or more embodiments, the third connection electrode CNE3 of the first intermediate electrode IET1 and a part (e.g., upper part) of the power line PL may be formed concurrently or substantially simultaneously using the same conductive material. In this case, the third connection electrode CNE3 of the first intermediate electrode IET1 and a part of the power line PL may include the same conductive material.

Each of the first insulating layer INS1, the second insulating layer INS2, and the third insulating layer INS3 may include at least one insulating material, and may be formed of a single layer or multiple layers. In one or more embodiments, each of the first insulating layer INS1, the second insulating layer INS2, and the third insulating layer INS3 may include silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or another inorganic insulating material.

In one or more embodiments, the first insulating layer INS1, the second insulating layer INS2, and the third insulating layer INS3 may be formed to have heights that are greater than or equal to the heights of the first light-emitting element LE1, the second light-emitting element LE2, and the third light-emitting element LE3, respectively. In one or more embodiments, the first insulating layer INS1, the second insulating layer INS2, and the third insulating layer INS3 may be planarized by a planarization process. Accordingly, the top surfaces of the first insulating layer INS1, the second insulating layer INS2, and the third insulating layer INS3 may be substantially flat. The first insulating layer INS1, the second insulating layer INS2, and the third insulating layer INS3 may include openings that expose partially expose the first light-emitting element LE1, the second light-emitting element LE2, and the third light-emitting element LE3, respectively.

The first passivation layer PSV1, the second passivation layer PSV2, and the third passivation layer PSV3 may be located in the entire display area DA to cover the first common electrode CME1, the second common electrode CME2, and the third common electrode CME3, respectively. In one or more embodiments, the first passivation layer PSV1, the second passivation layer PSV2, and the third passivation layer PSV3 may be planarized by a planarization process. Accordingly, the top surfaces of the first passivation layer PSV1, the second passivation layer PSV2, and the third passivation layer PSV3 may be substantially flat.

Each of the first passivation layer PSV1, the second passivation layer PSV2, and the third passivation layer PSV3 may include an insulating material, and may have a single-layer or multilayer structure. In one or more embodiments, each of the first passivation layer PSV1, the second passivation layer PSV2, and the third passivation layer PSV3 may include an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or another inorganic insulating material), but is not limited thereto.

The lens LS may be located on the light-emitting element layer EDL. For example, a lens array (e.g., microlens array) including the lenses LS overlapping the respective light-emitting elements LE may be located on the first passivation layer PSV1. In one or more embodiments, the lens LS may have a size corresponding to that of the emission area EA of each pixel PX, and may completely overlap the light-emitting element LE located in each pixel PX. For example, the lens LS may be a microlens corresponding to the size of the light-emitting element LE, and may have a size greater than the size of the light-emitting element LE in plan view to cover the light-emitting element LE and the periphery of the light-emitting element LE.

In one or more embodiments, the lens LS may be a microlens in the form of a convex lens provided at the upper side of the light-emitting elements LE, but the type, shape and/or size of the lens LS is not limited thereto. By placing the lens LS at the upper side of the light-emitting elements LE, the light emission characteristics of the pixels PX may be adjusted or improved.

The lens LS may be formed of a transparent material such that light incident from the light-emitting elements LE may be transmitted. As an example, the lens LS may be formed of glass, plastic, ceramic, or other materials, and may be formed of an optical material with a relatively high refractive index.

In accordance with the display device 10 including the display panel 100 described above, different types of light-emitting elements LE may be suitably located on the backplane substrate BPL by sequentially bonding the light-emitting elements LE emitting lights of different colors on the backplane substrate BPL. Because, however, the light-emitting elements LE emitting lights of different colors are located in different layers, the thickness of the light-emitting element layer EDL may increase, and the light path for the light emitted from at least some of the light-emitting elements LE (e.g., the second light-emitting elements LE2 that are farthest from the lens LS) to reach the lens LS may be increased. Accordingly, the light efficiency of at least some of the pixels PX may deteriorate.

Accordingly, in one or more embodiments, the light efficiency of the pixels PX may be increased by surrounding the side surfaces of the light-emitting elements LE with the reflective film RF. However, light reflected along various paths in the light-emitting element layer EDL may be directed in different directions with respective directionalities. Accordingly, the light collection efficiency of light that has reached the lens LS may deteriorate.

Accordingly, in additional embodiments, openings having various shapes (e.g., a slit shape, a mesh shape, a concentric shape, or a dot shape in plan view) may be formed in the common electrode CME to control the directionality or path of light directed from the light-emitting elements LE to the lens LS, and the light efficiency of the pixels PX may be improved. A detailed description thereof will be given later.

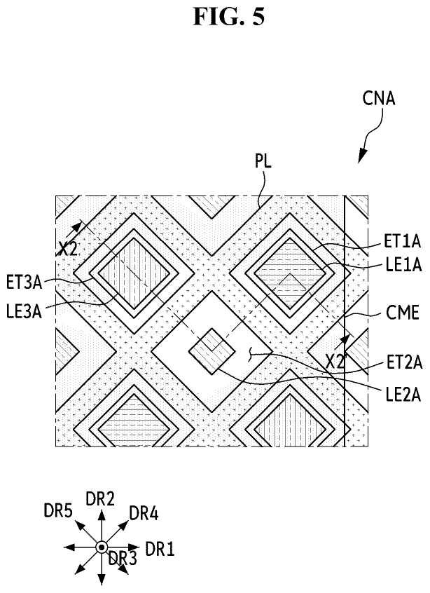

FIG. 5 is a plan view illustrating a common electrode connection area of a display device according to one or more embodiments. For example, FIG. 5 schematically shows a part of the common electrode connection area CNA shown in FIG. 1.

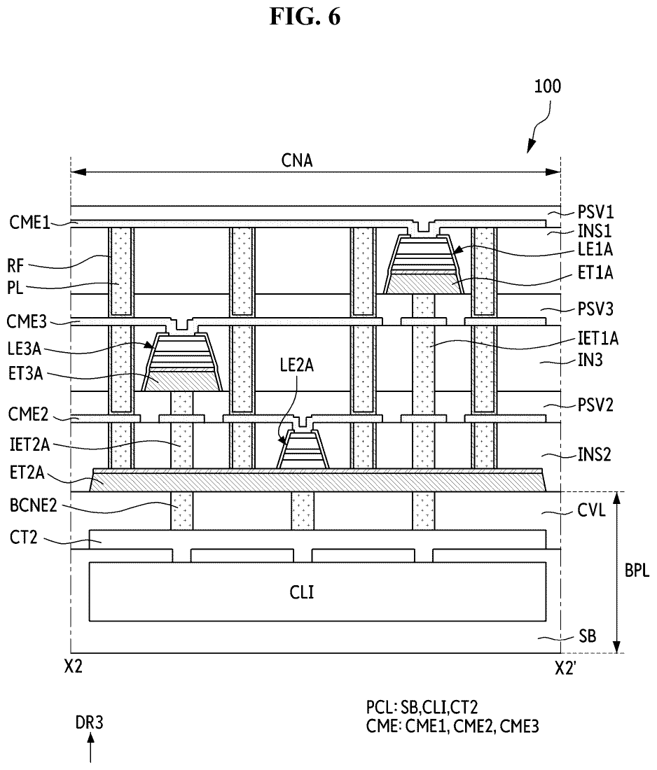

FIG. 6 is a cross-sectional view illustrating a display panel according to one or more embodiments. For example, FIG. 6 shows one or more embodiments of a cross-section of the display panel 100 taken along the line X2-X2′ of FIG. 5, which is a schematic cross-section of a part of the common electrode connection area CNA illustrated in FIG. 5.

Referring to FIGS. 5 and 6 in addition to FIGS. 1 to 4, the common electrode CME and the power line PL may also be located in the common electrode connection area CNA. The common electrode CME and the power line PL may be connected to at least one conductive pattern ET2A located on the backplane substrate BPL in the common electrode connection area CNA, and may be electrically connected to a connection line CLI formed in the backplane substrate BPL through the conductive pattern ET2A. In one or more embodiments, the conductive pattern ET2A and the connection line CLI may be electrically connected to each other through a second contact terminal CT2 and at least one connection electrode BCNE2 formed in the common electrode connection area CNA of the backplane substrate BPL.

In one or more embodiments, a plurality of light-emitting elements LE1A, LE2A, and LE3A may also be located in the common electrode connection area CNA, and the common electrode connection area CNA may have a cross-sectional structure similar to the cross-sectional structure of the display area DA. For example, the first light-emitting elements LE1A, the second light-emitting elements LE2A, and the third light-emitting elements LE3A, which are located or formed concurrently or substantially simultaneously with the first light-emitting elements LE1, the second light-emitting elements LE2, and the third light-emitting elements LE3 of the display area DA, respectively, may be located in the common electrode connection area CNA. Further, conductive patterns ET1A, ET2A, and ET3A and intermediate electrodes IET1A and IET2A may be located under the first light-emitting elements LE1A, the second light-emitting elements LE2A, and the third light-emitting elements LE3A of the common electrode connection area CNA. The conductive patterns ET1A, ET2A, and ET3A and the intermediate electrodes IET1A and IET2A of the common electrode connection area CNA may be respectively located or formed concurrently or substantially simultaneously with the electrodes ET and the intermediate electrodes IET of the display area DA.

A voltage that may turn off the light-emitting elements LE1A, LE2A, and LE3A located in the common electrode connection area CNA may be applied to the light-emitting elements LE1A, LE2A, and LE3A. For example, the same common voltage may be applied to both ends (e.g., the first contact electrode CTE1 and the second contact electrode CTE2) of each of the light-emitting elements LE1A, LE2A, and LE3A located in the common electrode connection area CNA. Accordingly, the light-emitting elements LE1A, LE2A, and LE3A of the common electrode connection area CNA may maintain an off state.

In one or more embodiments, the conductive pattern ET2A located under the second light-emitting elements LE2A of the common electrode connection area CNA may extend to an area overlapping the first light-emitting elements LE1A and the third light-emitting elements LE3A of the common electrode connection area CNA, and may be electrically connected to the conductive patterns ET1A and ET3A that are respectively under the first light-emitting elements LE1A and the third light-emitting elements LE3A. Further, the conductive pattern ET2A located under the second light-emitting elements LE2A of the common electrode connection area CNA may also be electrically connected to the power line PL and the common electrode CME. Accordingly, a common voltage may be applied to both ends of the first light-emitting elements LE1A, the second light-emitting elements LE2A, and the third light-emitting elements LE3A of the common electrode connection area CNA.

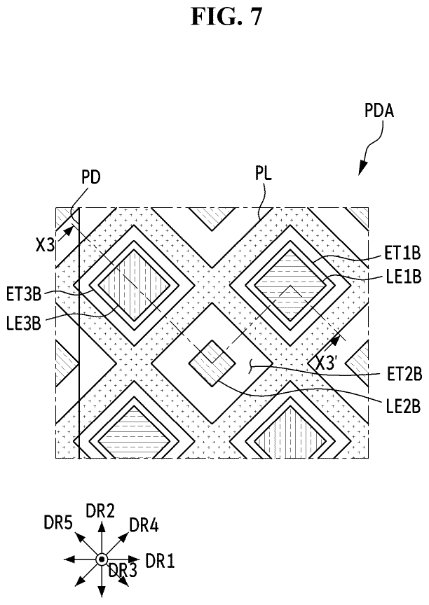

FIG. 7 is a plan view illustrating a pad area of a display device according to one or more embodiments. For example, FIG. 7 schematically shows a part of the pad area PDA shown in FIG. 1.

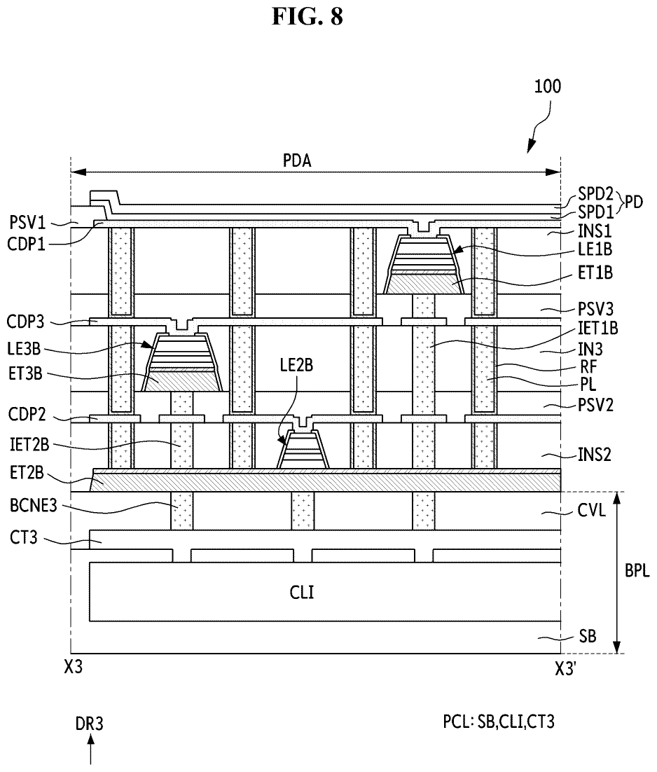

FIG. 8 is a cross-sectional view illustrating a display panel according to one or more embodiments. For example, FIG. 8 shows one or more embodiments of a cross-section of the display panel 100 taken along the line X3-X3′ of FIG. 7, which is a schematic cross-section of a part of the pad area PDA illustrated in FIG. 7.

Referring to FIGS. 7 and 8 in addition to FIGS. 1 to 6, the power line PL (or vertical connection line) may also be located in the pad area PDA. The power line PL may be electrically connected to at least one pad PD located in the pad area PDA, and may receive a common voltage from the pad PD.

The pad PD may be formed of at least one conductive layer. For example, the pad PD may be formed of multiple layers including a first pad layer SPD1 and a second pad layer SPD2 including different conductive materials.

In one or more embodiments, the pad area PDA may have a cross-sectional structure similar to that of the display area DA and/or the common electrode connection area CNA. For example, the first light-emitting elements LE1B, the second light-emitting elements LE2B, and the third light-emitting elements LE3B, which are located or formed concurrently or substantially simultaneously with the first light-emitting elements LE1, the second light-emitting elements LE2, and the third light-emitting elements LE3 of the display area DA, respectively, may be located in the pad area PDA. Further, conductive patterns ET1B, ET2B, and ET3B and intermediate electrodes IET1B and IET2B may be located under the first light-emitting elements LE1B, the second light-emitting elements LE2B, and the third light-emitting elements LE3B of the pad area PDA, and transparent electrodes CDP1, CDP2, and CDP3 may be located above the first light-emitting elements LE1B, second light-emitting elements LE2B, and third light-emitting elements LE3B of the pad area PDA. The conductive patterns ET1B, ET2B, and ET3B and the intermediate electrodes IET1B and IET2B of the pad area PDA may be located or formed concurrently or substantially simultaneously with the electrodes ET and the intermediate electrodes IET of the display area DA. The transparent electrodes CDP1, CDP2, and CDP3 of the pad area PDA may be located or formed concurrently or substantially simultaneously with the first common electrode CME1, the second common electrode CME2, and the third common electrode CME3 of the display area DA. Each of the transparent electrodes CDP1, CDP2, and CDP3 of the pad area PDA may be formed integrally with the first common electrode CME1, the second common electrode CME2, or the third common electrode CME3 of the display area DA, or may be formed separately from the first common electrode CME1, the second common electrode CME2, or the third common electrode CME3 of the display area DA.

The conductive patterns ET1B, ET2B, and ET3B, the transparent electrodes CDP1, CDP2, and CDP3, and the power line PL of the pad area PDA may be commonly connected to at least one pad PD to which a common voltage is applied. Accordingly, a common voltage may be applied to the conductive patterns ET1B, ET2B, and ET3B, the transparent electrodes CDP1, CDP2, and CDP3, and the power line PL of the pad area PDA, and the light-emitting elements LE1B, LE2B, and LE3B of the pad area PDA may maintain an off state.

The conductive patterns ET1B, ET2B, and ET3B, the transparent electrodes CDP1, CDP2, and CDP3, and the power line PL of the pad area PDA may be electrically connected to the connection line CLI through at least one connection electrode BCNE3 and a third contact terminal CT3 formed in the backplane substrate BPL in the pad area PDA. The connection line CLI may extend from the pad area PDA to the common electrode connection area CNA, and may electrically connect the third contact terminal CT3 of the pad area PDA to the second contact terminal CT2 of the common electrode connection area CNA. Accordingly, the common voltage applied through the pad PD electrically connected to the connection line CLI may be transmitted from the common electrode connection area CNA to the common electrode CME.

When the light-emitting elements LE are also located in the non-display area NDA including the common electrode connection area CNA and the pad area PDA as in the embodiments of FIGS. 5 to 8, the display area DA and the non-display area NDA of the display panel 100 may have similar cross-sectional structures or heights. Accordingly, the planarization process for planarizing each light-emitting element layer EDL (e.g., the first light-emitting element layer EDL1, the second light-emitting element layer EDL2, and the third light-emitting element layer EDL3) may be performed more smoothly, and the high-quality display device 10 may be manufactured.

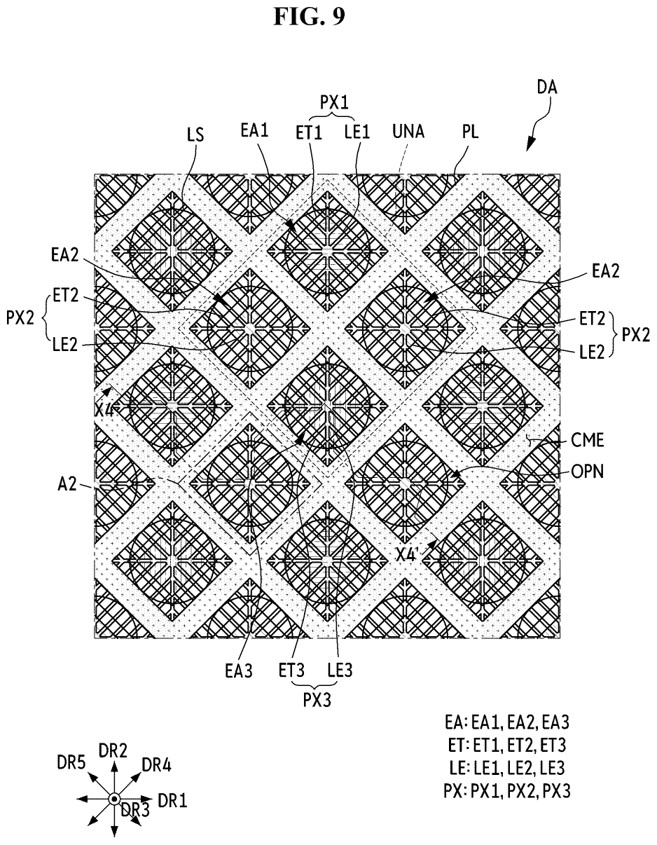

FIG. 9 is a plan view illustrating a display area of a display device according to one or more embodiments. For example, FIG. 9 schematically shows a part of the display area DA illustrated in FIG. 1, and shows one or more embodiments different from the one or more embodiments corresponding to FIG. 2 in relation to the common electrode CME.

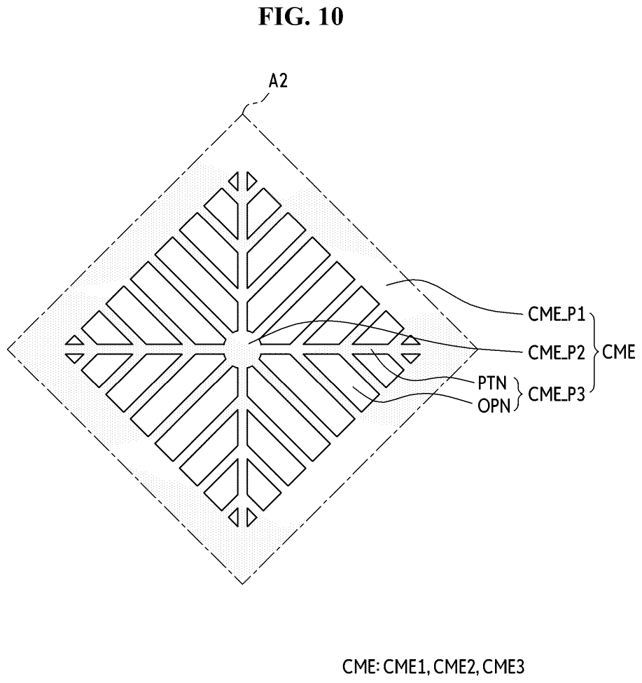

FIG. 10 is a plan view showing a common electrode according to one or more embodiments. For example, FIG. 10 shows one or more embodiments of a part of the common electrode CME located in area A2 of FIG. 9.

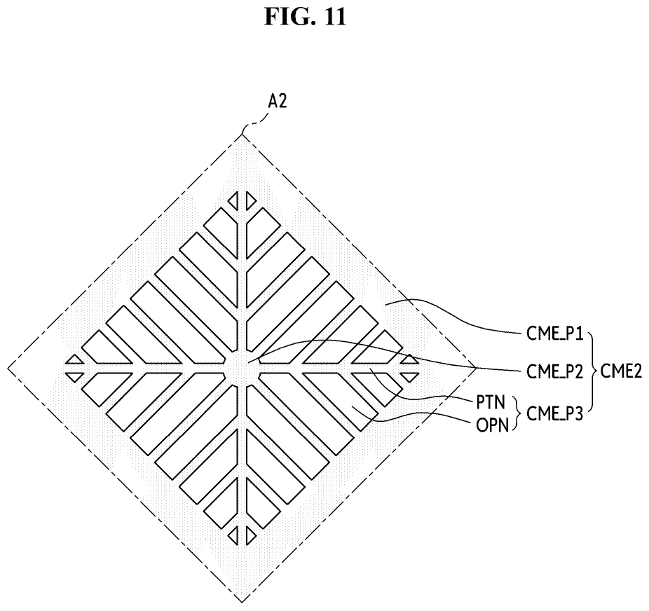

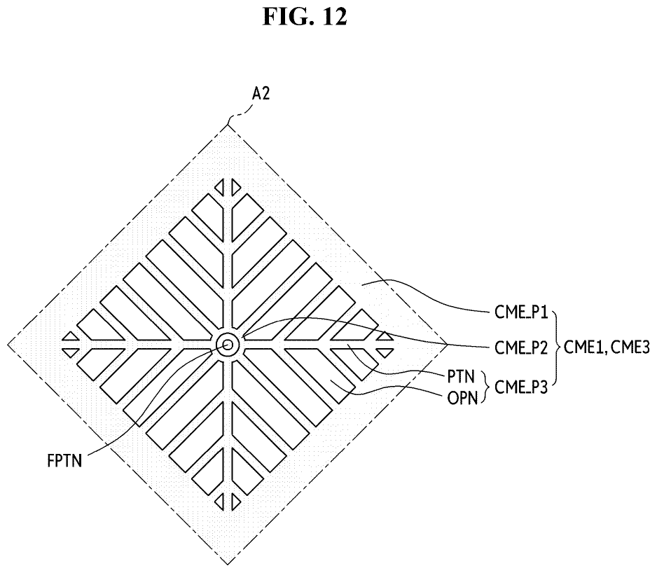

FIGS. 11 and 12 are plan views showing a common electrode according to one or more embodiments. For example, FIG. 11 shows one or more embodiments of a part of the second common electrode CME2 located in area A2 of FIG. 9, and FIG. 12 shows one or more embodiments of a part of the first common electrode CME1 and the third common electrode CME3 located in the area A2 of FIG. 9.

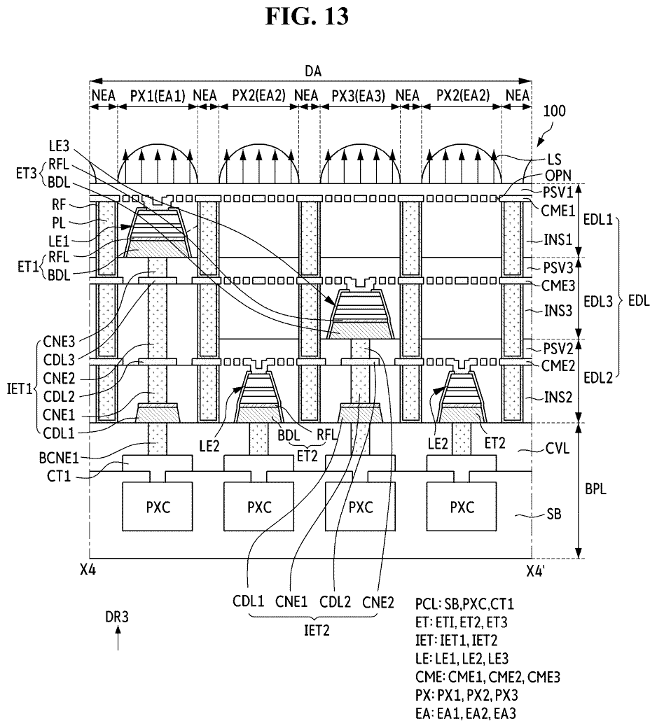

FIG. 13 is a cross-sectional view illustrating a display panel according to one or more embodiments. For example, FIG. 13 illustrates one or more embodiments of a cross section of the display panel 100 taken along the line X4-X4′ of FIG. 9.

In describing the following embodiments, components substantially identical or similar to those of at least one or more embodiments described above are designated with the same reference numerals, and redundant descriptions will be omitted.

Referring to FIGS. 9 to 13, the common electrode CME may be opened to include/define a plurality of openings OPN in each emission area EA. The openings OPN of the common electrode CME may be located at generally uniform intervals in each emission area EA, or at least a part of the emission area EA, but the embodiments are not limited thereto.

The common electrode CME may be formed in a structure capable of improving or optimizing the light emission efficiency of light emitted from each light-emitting element LE. For example, the common electrode CME may be formed in a scattering pattern or a polarization pattern capable of scattering or polarizing light generated in each emission area EA. For example, the common electrode CME may include a scattering pattern formed of patterns PTN and the openings OPN in each emission area EA. In one or more embodiments, the scattering pattern may include at least one of a micro-pattern formed of the patterns PTN of a nanometer or micrometer size and the openings OPN, a lattice pattern with a regularly arranged lattice structure, or an irregular pattern having an irregular arrangement. For example, the common electrode CME may have a lattice structure, such as a mesh shape or a vertical stripe shape, in each emission area EA.

The common electrode CME may not be opened at a portion connected to the light-emitting element LE located in each emission area EA, and the portion connected to the light-emitting element LE may extend to the non-emission area NEA.

For example, the first common electrode CME1 connected to the first light-emitting element LE1 in the first emission area EA1 may be integrally formed in the first emission area EA1 and the non-emission area NEA around the first emission area EA1, and may be opened to include/define the plurality of openings OPN at other portions of the first emission area EA1 except the contact portion connected to the first light-emitting element LE1.

The second common electrode CME2 connected to the second light-emitting element LE2 in the second emission area EA2 may be integrally formed in the second emission area EA2 and the non-emission area NEA around the second emission area EA2, and may be opened to include/define the plurality of openings OPN at other portions of the second emission area EA2 except the contact portion connected to the second light-emitting element LE2.

The third common electrode CME3 connected to the third light-emitting element LE3 in the third emission area EA3 may be integrally formed in the third emission area EA3 and the non-emission area NEA around the third emission area EA3, and may be opened to include/define the plurality of openings OPN at other portions of the third emission area EA3 except the contact portion connected to the third light-emitting element LE3.

In one or more embodiments, the first common electrode CME1, the second common electrode CME2, and the third common electrode CME3 may have substantially the same shape in each emission area EA, and may substantially completely overlap in plan view. For example, as illustrated in FIG. 10, the first common electrode CME1 and the third common electrode CME3 that are not directly connected to the second light-emitting element LE2 in the second emission area EA2 may also have substantially the same planar shape as that of the second common electrode CME2, and may overlap the second common electrode CME2. However, the embodiments are not limited thereto, and the shapes of the first common electrode CME1, the second common electrode CME2, and the third common electrode CME3 may vary according to the embodiments.

The common electrode CME may include a first portion CME_P1 located in the non-emission area surrounding the emission areas EA and surrounding the respective light-emitting elements LE in plan view, second portions CME_P2 located in the respective emission areas EA and located on at least a part of the respective light-emitting elements LE, and third portions CME_P3 located between the first portion CME_P1 and the second portions CME_P2 and including/defining the openings OPN and the patterns PTN that are repeated in a lattice structure of a corresponding shape.

For example, the first portion CME_P1 of the common electrode CME may be a frame portion of a lattice structure that has a mesh shape in the display area DA and that is located in the entire non-emission area NEA. The first portion CME_P1 of the common electrode CME may surround the light-emitting elements LE located in the emission areas EA in plan view.

The second portion CME_P2 of the common electrode CME may include a contact area where the common electrode CME is connected to the light-emitting element LE in each emission area EA.

The third portion CME_P3 of the common electrode CME may be an area between the contact area and the frame portion of the common electrode CME, and may be an area where the openings OPN are formed. The third portion CME_P3 of the common electrode CME may have various shapes capable of changing or controlling the path of light emitted from each light-emitting element LE. The third portion CME_P3 of the common electrode CME may also be referred to as “scattering pattern” or “polarization pattern.” In one or more embodiments, in at least a part of the third portion CME_P3 of the common electrode CME, the patterns PTN and the openings OPN may be located at uniform intervals. Accordingly, the path of light passing through the third portion CME_P3 of the common electrode CME may become more uniform.

For example, the first common electrode CME1 may include the first portion CME_P1 located in the non-emission area NEA of the display area DA and surrounding the emission areas EA of the display area DA including the first emission area EA1, the second portion CME_P2 located on at least a part of the first light-emitting element LE1 in each first emission area EA1 and electrically connected to the first light-emitting element LE1, and the third portion CME_P3 located between the first portion CME_P1 and the second portion CME_P2 (the first portion CME_P1 and the second portion CME_P2 of the first common electrode CME1) and including the patterns PTN and the openings OPN between the patterns PTN.

The second common electrode CME2 may include the first portion CME_P1 located in the non-emission area NEA of the display area DA and surrounding the emission areas EA of the display area DA including the second emission area EA2, the second portion CME_P2 located on at least a part of the second light-emitting element LE2 in each second emission area EA2 and electrically connected to the second light-emitting element LE2, and the third portion CME_P3 located between the first portion CME_P1 and the second portion CME_P2 (the first portion CME_P1 and the second portion CME_P2 of the second common electrode CME2) and including the patterns PTN and the openings OPN between the patterns PTN.

The third common electrode CME3 may include the first portion CME_P1 located in the non-emission area NEA of the display area DA and surrounding the emission areas EA of the display area DA including the third emission area EA3, the second portion CME_P2 located on at least a part of the third light-emitting element LE3 in each third emission area EA3 and electrically connected to the third light-emitting element LE3, and the third portion CME_P3 located between the first portion CME_P1 and the second portion CME_P2 (the first portion CME_P1 and the second portion CME_P2 of the third common electrode CME3) and including the patterns PTN and the openings OPN between the patterns PTN.

The patterns PTN and the openings OPN of the first common electrode CME1 may also be referred to as “first patterns” and “first openings,” respectively. The patterns PTN and the openings OPN of the second common electrode CME2 may also be referred to as “second patterns” and “second openings,” respectively. The patterns PTN and the openings OPN of the third common electrode CME3 may also be referred to as “third patterns” and “third openings,” respectively.

In one or more embodiments, the common electrode CME may include/define the openings OPN having a planar shape, such as a slit shape, a mesh shape, a concentric shape, or a dot shape, at the third portion CME_P3, and the patterns PTN located between the openings OPN may have a planar shape, such as a bar shape, a mesh shape, a radial shape, a concentric shape, or a stem shape. In one or more embodiments, the patterns PTN of the third portion CME_P3 of the common electrode CME may be integrated with the first portion CME_P1 and the second portion CME_P2 of the common electrode CME. For example, the patterns PTN of the third portion CME_P3 of the first common electrode CME1 may be integrated with the first portion CME_P1 and the second portion CME_P2 of the first common electrode CME1. The patterns PTN of the third portion CME_P3 of the second common electrode CME2 may be integrated with the first portion CME_P1 and the second portion CME_P2 of the second common electrode CME2. The patterns PTN of the third portion CME_P3 of the third common electrode CME3 may be integrated with the first portion CME_P1 and the second portion CME_P2 of the third common electrode CME3.

In one or more embodiments, when the common electrode CME includes a plurality of openings in each emission area EA, the common electrode CME may include a transparent conductive material or an opaque conductive material. For example, the common electrode CME may include indium tin oxide (ITO), indium zinc oxide (IZO) or another transparent conductive material, or may include titanium (Ti), titanium nitride (TiN), aluminum (Al), aluminum-copper alloy (AlCu), nickel (Ni), chromium (Cr), or another conductive material.

In each of the emission areas EA, the second portion CME_P2 may be located at the center (e.g., generally at the center), and the third portion CME_P3 may be located outside the second portion CME_P2. For example, in the area A2 including one second emission area EA2 and the non-emission area NEA surrounding the second emission area EA2, the first portion CME_P1 may be positioned in the non-emission area NEA corresponding to the edge of the area A2, the second portion CME_P2 may be positioned at/near the center of the area A2 corresponding to the center of the second emission area EA2, and the third portion CME_P3 may be positioned in the second emission area EA2 and may be positioned between the first portion CME_P1 and the second portion CME_P2.

At least one of the first common electrode CME1, the second common electrode CME2, or the third common electrode CME3, which electrically form one common electrode CME and are located in different layers, may be located in each emission area EA. For example, the first common electrode CME1 may be located in the first emission area EA1, the first common electrode CME1, the second common electrode CME2, and the third common electrode CME3 may be located in the second emission area EA2, and the first common electrode CME1 and the third common electrode CME3 may be located in the third emission area EA3.

In the common electrode CME directly connected to the corresponding light-emitting element LE in each emission area EA, the first portion CME_P1 and the second portion CME_P2 may be integrally connected through at least one pattern PTN of the third portion CME_P3. For example, in the first common electrode CME1, the first portion CME_P1 and the second portion CME_P2 may be integrally connected through the plurality of patterns PTN of the third portion CME_P3 at least in the first emission area EA1. In the second common electrode CME2, the first portion CME_P1 and the second portion CME_P2 may be integrally connected through the plurality of patterns PTN of the third portion CME_P3 at least in the second emission area EA2. In the third common electrode CME3, the first portion CME_P1 and the second portion CME_P2 may be integrally connected through the plurality of patterns PTN of the third portion CME_P3 at least in the third emission area EA3.

In one or more embodiments, in the emission areas EA where at least two common electrodes CME among the first common electrode CME1, the second common electrode CME2, and the third common electrode CME3 are located, the at least two common electrodes CME may have the same shape (e.g., the same planar shape). For example, as illustrated in FIG. 10, in the second emission area EA2, the first common electrode CME1, the second common electrode CME2, and the third common electrode CME3 may have substantially the same planar shape and may substantially completely overlap.

In one or more other embodiments, in the emission areas EA where at least two common electrodes CME among the first common electrode CME1, the second common electrode CME2, and the third common electrode CME3 are located, the at least two common electrodes CME may have different shapes (e.g., different planar shapes). For example, as illustrated in FIGS. 11, 12, and 13, in the second emission area EA2, the second common electrode CME2 may not be opened at the second portion CME_P2 connected to the second light-emitting element LE2, whereas the first common electrode CME1 and the third common electrode CME3 may include at least one opening OPN located inside the second portion CME_P2. In one or more embodiments, an electrically isolated floating pattern FPTN may be located inside the opening OPN formed at the second portion CME_P2 of the first common electrode CME1 and the third common electrode CME3 (e.g., see FIG. 12), or the opening may be formed without the floating pattern FPTN. In one or more embodiments, the first common electrode CME1 and the third common electrode CME3 may have the same shape as the second common electrode CME2 in the first emission area EA1 and the third emission area EA3, respectively, but the embodiments are not limited thereto.

FIGS. 11, 12, and 13 illustrate that the third portions CME_P3 of at least two common electrodes CME have planar shapes corresponding to each other (for example, substantially the same planar shapes) in the emission areas EA where the at least two common electrodes CME are located, but the embodiments are not limited thereto. For example, in the emission areas EA where at least two common electrodes CME are located, the at least two common electrodes CME may have different planar shapes. For example, the at least two common electrodes CME may include/define the openings OPN of different shapes, sizes, and/or numbers.

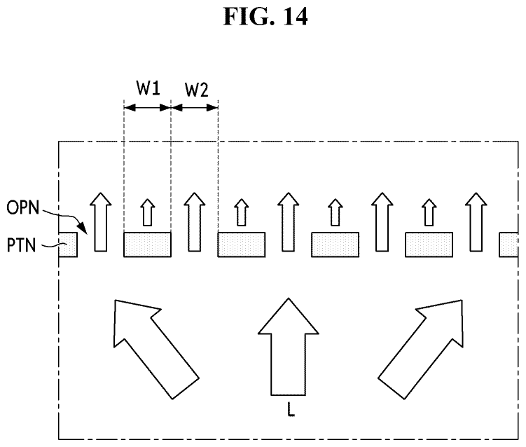

FIG. 14 is a drawing showing a polarization effect obtained by a common electrode according to one or more embodiments.

Referring to FIG. 14 in addition to FIGS. 9 to 13, the patterns PTN and the openings OPN may be located alternately and/or repeatedly at the third portion CME_P3 of the common electrode CME. Accordingly, light L emitted from each light-emitting element LE and directed to the common electrode CME along various paths may be polarized in a certain direction while transmitting through the common electrode CME. The polarized light may reach the lens LS along a more uniform path. Accordingly, the light collection efficiency of the lens LS may be increased, and the light efficiency (e.g., the light emission efficiency of light emitted from the light-emitting elements LE) of the pixels PX may be improved.

The width or pitch of the patterns PTN and the openings OPN constituting the third portion CME_P3 of the common electrode CME may be variously changed according to embodiments. For example, a width W1 of the pattern PTN and a width W2 of the opening OPN may be the same or substantially the same, but the present disclosure is not limited thereto. For example, the ratio of the width W1 of the pattern PTN and the width W2 of the opening OPN may be 1:1, 1:2, or another value. Further, in each emission area EA, the width W1 of the pattern PTN and the width W2 of the opening OPN, or the pitch may be uniform overall, or different for each portion.

In one or more embodiments, in consideration of the overall light emission efficiency of light generated in the first emission area EA1, the second emission area EA2, and the third emission area EA3, the openings OPN having substantially the same size, number, and/or shape may be formed at the common electrode CME in the first emission area EA1, the second emission area EA2, and the third emission area EA3. In one or more other embodiments, the openings OPN having different sizes, numbers, and/or shapes may be formed at the common electrode CME for each emission area EA to improve or optimize the light emission efficiency of light emitted from each of the first emission area EA1, the second emission area EA2, and the third emission area EA3.

In one or more embodiments, the common electrode CME having a shape that may improve or optimize the light efficiency of the pixels PX may be designed by simulation, and the common electrode CME may be formed in response thereto. For example, the common electrode CME may be designed to include the patterns PTN and the openings OPN having a shape, number, and/or size that may optimize the light emission efficiency of the pixels PX by simulation, and the common electrode CME may be formed according to the designed structure.

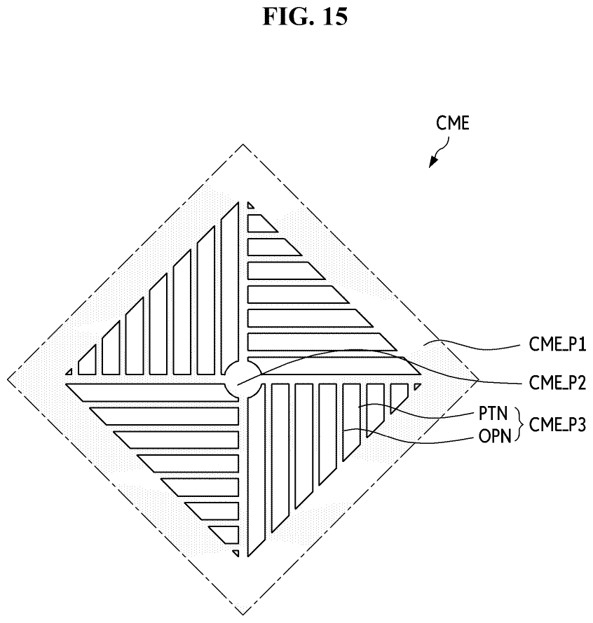

FIGS. 15 to 19 are plan views showing common electrodes according to respective embodiments. For example, FIGS. 15 to 19 show different embodiments of a part of the common electrode CME located in one emission area EA, and the non-emission area NEA around the emission area EA. FIGS. 15 to 19 show embodiments that are different from the embodiments of FIGS. 10 to 12 in relation to the third portion CME_P3 of the common electrode CME.

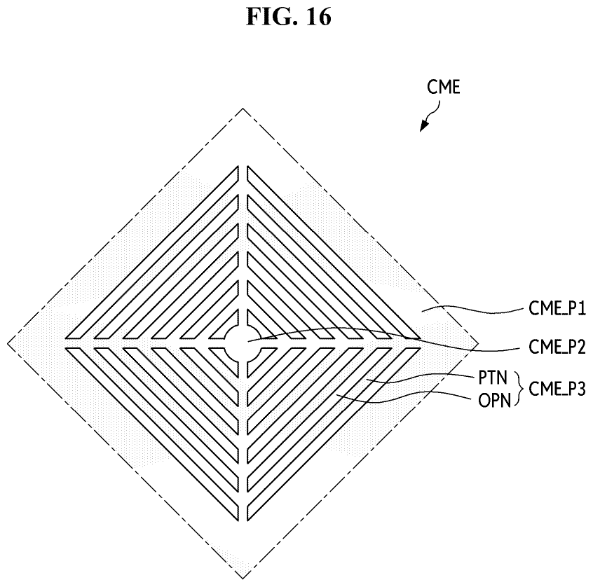

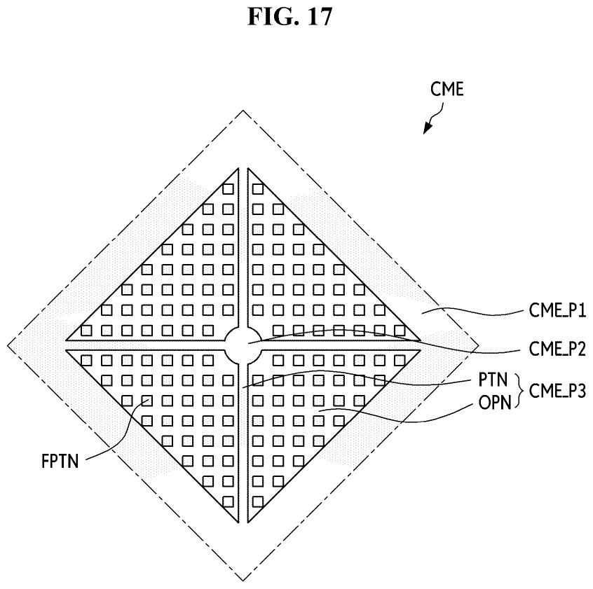

Referring to FIGS. 15 to 17 in addition to FIGS. 9 to 14, the common electrode CME may include the first portion CME_P1, the second portion CME_P2, and the third portion CME_P3, third portion CME_P3 including the openings OPN of various shapes and/or sizes. For example, at least one common electrode CME (e.g., at least one common electrode CME including the common electrode CME directly connected to the light-emitting element LE in each emission area EA among the first common electrode CME1, the second common electrode CME2, and the third common electrode CME3 located in different layers) located in each emission area EA may include the first portion CME_P1, the second portion CME_P2, and the third portion CME_P3, and may include the patterns PTN and the openings OPN having shapes according to the one or more embodiments corresponding to FIG. 15, FIG. 16, or FIG. 17.

In each emission area EA, the common electrode CME may include the patterns PTN having a bar shape, a mesh shape, a radial shape, or another lattice shape, and the openings OPN located between the patterns PTN and having a planar shape, such as a slit shape, a mesh shape, a concentric shape, or a dot shape. In one or more embodiments, the floating pattern FPTN, which is formed of the same material as the common electrode CME, is in the same layer as the common electrode CME, and is separated from the common electrode CME, may be further located in each emission area EA. For example, as illustrated in FIG. 17, the floating patterns FPTN having a dot shape or another shape may be located in each emission area EA, so that the conductive layer including the common electrode CME may have a multi-pattern shape in which the bar-shaped patterns PTN and the dot-shaped floating patterns FPTN are mixed in each emission area EA.

In one or more embodiments, the common electrode CME may have a uniform shape in the emission areas EA. For example, the first common electrode CME1 may have substantially the same planar shape in the first emission area EA1, the second emission area EA2, and the third emission area EA3, the second common electrode CME2 may have substantially the same planar shape as the first common electrode CME1 in the second emission area EA2, and the third common electrode CME3 may have substantially the same planar shape as the first common electrode CME1 in the second emission area EA2 and the third emission area EA3.

However, the embodiments are not limited thereto. For example, the common electrode CME may be formed in different shapes for each emission area EA and/or each layer. For example, the planar shape of the common electrode CME may be differentiated for each emission area EA and/or each layer to improve or optimize the light efficiency of the pixels PX.

In one or more embodiments, the common electrode CME may be formed in different shapes in at least two emission areas EA among the first emission area EA1, the second emission area EA2, and the third emission area EA3. For example, the pattern shape of the common electrode CME may be differentiated for each emission area EA to optimize the light emission efficiency of each of the first pixel PX1, the second pixel PX2, and the third pixel PX3. For example, the first common electrode CME1 may include the second portion CME_P2 and the third portion CME_P3 in the first emission area EA1 as in the embodiments of FIGS. 10 and 15 to 17, and may be partially or entirely opened to include at least one opening OPN in the second emission area EA2 and the third emission area EA3 without including at least one of the second portion CME_P2 or the third portion CME_P3. Similarly, the third common electrode CME3 may include the second portion CME_P2 and the third portion CME_P3 in the third emission area EA3 as in the embodiments of FIGS. 10 and 15 to 17, and may be partially or entirely opened to include at least one opening OPN in the second emission area EA2 without including at least one of the second portion CME_P2 or the third portion CME_P3.

In one or more embodiments, at least two common electrodes CME among the first common electrode CME1, the second common electrode CME2, and the third common electrode CME3 may be formed in different shapes. For example, when at least two common electrodes CME among the first common electrode CME1, the second common electrode CME2, and the third common electrode CME3 are located in one emission area EA as in the second emission area EA2 or the third emission area EA3, the at least two common electrodes CME may have different planar shapes. For example, in the second emission area EA2, the first common electrode CME1 may have a shape according to the one or more embodiments corresponding to FIG. 17, the second common electrode CME2 may have a shape according to the one or more embodiments corresponding to FIG. 16, and the third common electrode CME3 may have a shape according to the one or more embodiments corresponding to FIG. 15. In addition, the shape of each of the first common electrode CME1, the second common electrode CME2, and the third common electrode CME3 may be variously changed according to embodiments.

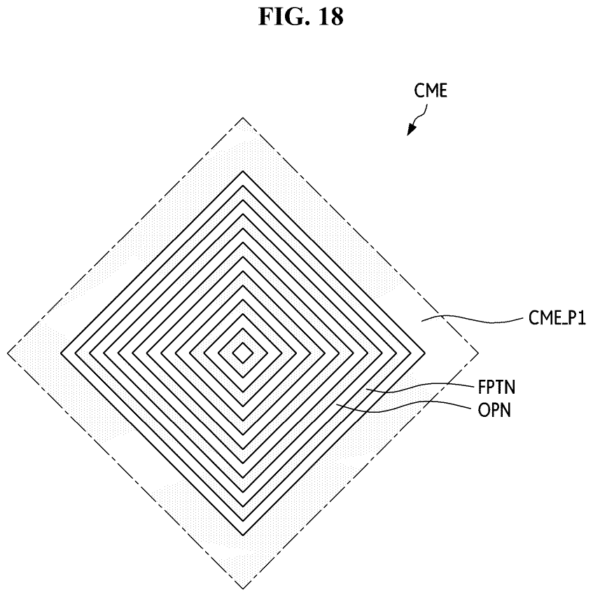

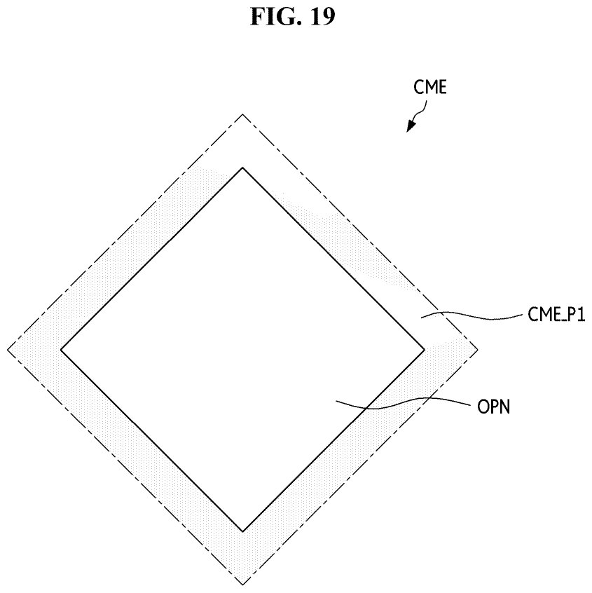

Referring to FIGS. 18 and 19 in addition to FIGS. 9 to 17, in at least one emission area EA, at least one common electrode CME may include only the first portion CME_P1, and may omit the second portion CME_P2 and the third portion CME_P3. For example, in at least one emission area EA, at least one common electrode CME that is not directly connected to the light-emitting element LE may include/define the opening OPN corresponding to the at least one emission area EA, and may omit the second portion CME_P2 and the third portion CME_P3. For example, in the second emission area EA2, the first common electrode CME1 and the third common electrode CME3 may include/define the opening OPN corresponding to the second emission area EA2. In one or more embodiments, also in the third emission area EA3, the first common electrode CME1 may include/define the opening OPN corresponding to the third emission area EA3, and may omit the second portion CME_P2 and the third portion CME_P3.

In one or more embodiments, in at least one emission area EA, there may be the floating pattern FPTN located in the same layer as at least one common electrode CME that is not directly connected to the light-emitting element LE, and spaced apart from the common electrode CME. For example, the floating patterns FPTN having a planar shape shown in FIG. 18 or another planar shape may be located in the second emission area EA2. The floating patterns FPTN may be located in the same layer as the first common electrode CME1 and/or the third common electrode CME3, and may be spaced apart from the first common electrode CME1 and/or the third common electrode CME3. In one or more embodiments, the floating patterns FPTN may also be located in the third emission area EA3. For example, in the third emission area EA3, the floating patterns FPTN located in the same layer as the first common electrode CME1 and spaced apart from the first common electrode CME1 may be located. In one or more other embodiments, in at least one emission area EA, a conductive layer including at least one common electrode CME that is not directly connected to the light-emitting element LE may include/define the opening OPN corresponding to the at least one emission area EA, and the floating pattern FPTN may not be located in the opening OPN. For example, in the second emission area EA2, the first common electrode CME1 and the third common electrode CME3 may be entirely opened as illustrated in FIG. 19. Similarly, in the third emission area EA3, the first common electrode CME1 may be entirely opened as illustrated in FIG. 19.

In one or more embodiments, in the second emission area EA2, the second common electrode CME2 may include the second portion CME_P2 and the third portion CME_P3 as in the embodiments of FIGS. 11, 15, 16, or 17, and each of the first common electrode CME1 and the third common electrode CME3 may include the second portion CME_P2 and the third portion CME_P3 as in the embodiments of FIGS. 10, 11, 15, 16, or 17, or may omit the second portion CME_P2 and the third portion CME_P3 as in the one or more embodiments corresponding to FIG. 18 or 19. Similarly, in the third emission area EA3, the third common electrode CME3 may include the second portion CME_P2 and the third portion CME_P3 as in the embodiments of FIGS. 10, 15, 16, or 17, and the first common electrode CME1 may include the second portion CME_P2 and the third portion CME_P3 as in the embodiments of FIGS. 10, 11, 15, 16, or 17, or may omit the second portion CME_P2 and the third portion CME_P3 as in the one or more embodiments corresponding to FIGS. 18 or 19.

As described above, according to the embodiments, the common electrode CME may include the patterns PTN and the openings OPN of various shapes in the emission areas EA. For example, the common electrode CME may have a lattice structure of various shapes and/or pitches in the emission areas EA.

In accordance with the display device 10 according to embodiments, the light efficiency of the pixels PX may be improved. For example, by polarizing the light generated in the light-emitting element LE of each pixel PX and directed along various paths by the common electrode CME according to embodiments, the path of the light may become more uniform. Accordingly, the light collection efficiency using the lens LS may be improved, and the light efficiency of the pixels PX and the display device 10 including the same may be improved.

The display device according to one or more embodiments of the present disclosure can be applied to various electronic devices. The electronic device according to the one or more embodiments of the present disclosure includes the display device described above, and may further include modules or devices having additional functions in addition to the display device.

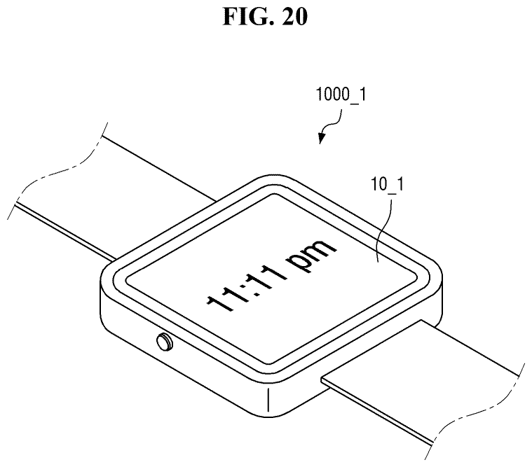

FIG. 20 is a diagram illustrating a smart watch including a display device according to one or more embodiments.

Referring to FIG. 20, a display device 10_1 according to one or more embodiments may be applied to a smart watch 1000_1 that is one of the smart devices.

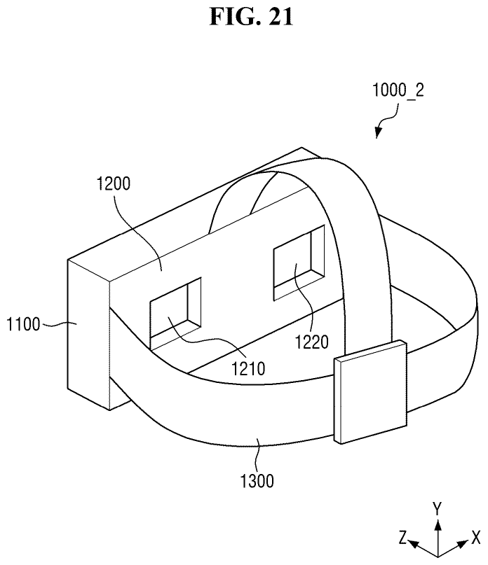

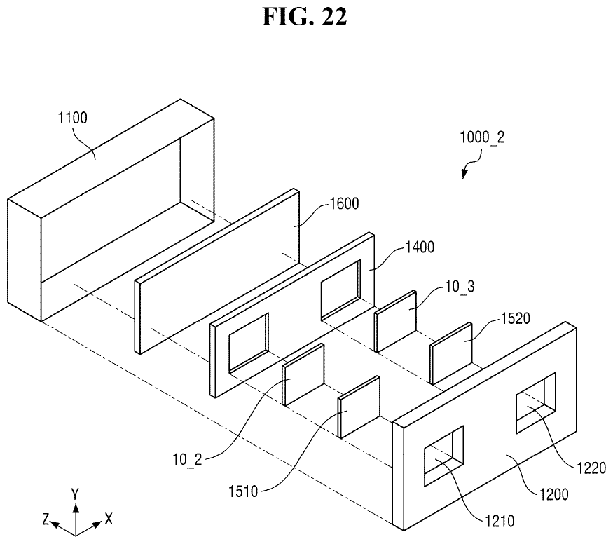

FIGS. 21 and 22 illustrate a head-mounted display including a display device according to one or more embodiments.

Referring to FIGS. 21 and 22, a head-mounted display 1000_2 according to one or more embodiments may be a virtual reality device. The head-mounted display 1000_2 includes a first display device 10_2, a second display device 10_3, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_2 provides an image to the user's left eye, and the second display device 10_3 provides an image to the user's right eye.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600, and between the second display device 10_3 and the control circuit board 1600. The middle frame 1400 serves to support and fix the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through the connector. The control circuit board 1600 may convert an image source inputted from the outside into video data, and may transmit the video data to the first display device 10_2 and the second display device 10_3 through the connector.

The control circuit board 1600 may transmit the video data corresponding to a left-eye image optimized for the user's left eye to the first display device 10_2, and may transmit the video data corresponding to a right-eye image optimized for the user's right eye to the second display device 10_3. Alternatively, the control circuit board 1600 may transmit the same video data to the first display device 10_2 and the second display device 10_3.

The display device housing 1100 serves to accommodate the first display device 10_2, the second display device 10_3, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 21 and 22 illustrate that the first eyepiece 1210 and the second eyepiece 1220 are located separately, but the embodiments are not limited thereto. For example, the first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. The user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

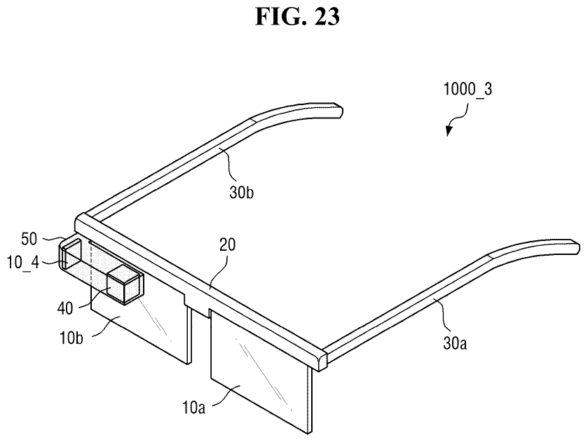

The head-mounted band 1300 serves to secure the display device housing 1100 to the user's head such that the first eyepiece 1210 and the second eyepiece 1220 of the housing cover 1200 remain located on the user's left and right eyes, respectively. When the display device housing 1100 is implemented to be lightweight and compact, the head-mounted display 1000_2 may be provided with, as shown in FIG. 23, an eyeglass frame instead of the head-mounted band 1300.

Additionally, the head-mounted display 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

FIG. 23 illustrates a head-mounted display including a display device according to one or more embodiments.

Referring to FIG. 23, a head-mounted display 1000_3 according to one or more embodiments may be a glasses-type device. The head-mounted display 1000_3 according to one or more embodiments may include the display device 10_4, a left eye lens 10a, a right eye lens 10b, a support frame 20, temples 30a and 30b, a reflection member 40, and a display device housing 50.

FIG. 23 illustrates that the head-mounted display 1000_3 is an eyeglasses-type display device including eyeglass frame legs 30a and 30b, but the embodiments are not limited thereto. For example, the head-mounted display 1000_3 may be applied in various forms in other electronic devices.

The display device housing 50 may include the display device 10_4 and the reflection member 40 (or an optical path changing member). An image displayed on the display device 10_4 may be reflected by the reflection member 40, and may be provided to the user's right eye through the right eye lens 10b. As a result, the user may view an augmented reality image, through the right eye, in which a virtual image displayed on the display device 10_4 and a real image seen through the right eye lens 10b are combined. In one or more embodiments, the display device housing 50 may further include an optical member located between the display device 10_4 and the reflection member 40. The image displayed on the display device 10_4 may be magnified by the optical member, and may be provided to the user's right eye through the right eye lens 10b after the optical path thereof is changed by the reflection member 40.

Although FIG. 23 illustrates that the display device housing 50 is located at the right end of the support frame 20, the present disclosure is not limited thereto. For example, the display device housing 50 may be located at the left end of the support frame 20, and in this case, the image displayed on the display device 10_4 may be reflected by the reflection member 40 and provided to a user's left eye through the left eye lens 10a. As a result, the user may view the image displayed on the display device 10_4 with the left eye. Alternatively, the display device housing 50 may be located at both the left end and the right end of the support frame 20, in which case the user can view the image displayed on the display device 10_4 through both the left eye and the right eye.

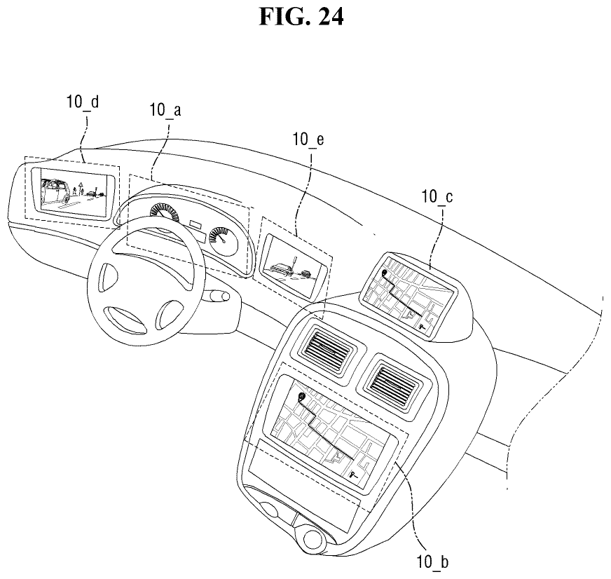

FIG. 24 is a diagram illustrating a dashboard of an automobile and a center fascia including display devices according to one or more embodiments. FIG. 14 illustrates a vehicle to which display devices 10_a, 10_b, 10_c, 10_d, and 10_e according to one or more embodiments are applied.

Referring to FIG. 24, the display devices 10_a, 10_b, and 10_c according to one or more embodiments may be applied to the dashboard of the automobile, the center fascia of the automobile, or the center information display (CID) of the dashboard of the automobile. Further, the display devices 10_d, and 10_e according to one or more embodiments may be applied to a room mirror display instead of side mirrors of the automobile.

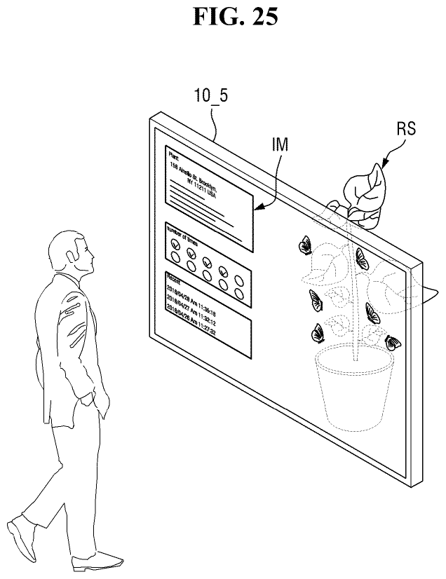

FIG. 25 is a diagram illustrating a transparent display device including a display device according to one or more embodiments.

Referring to FIG. 25, the display device 10_5 according to one or more embodiments may be applied to the transparent display device. The transparent display device may display an image IM, and also may transmit light. Thus, a user located on the front side of the transparent display device can view an object RS or a background on the rear side of the transparent display device as well as the image IM displayed on the display device 10_5. When the display device 10_5 is applied to the transparent display device, the substrate of the display device 10_5 may include a light-transmitting portion capable of transmitting light or may be made of a material capable of transmitting light.

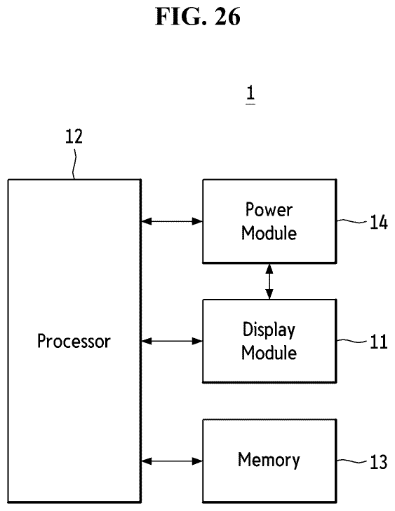

FIG. 26 is a block diagram of an electronic device according to one or more embodiments of the present disclosure.

Referring to FIG. 26, the electronic device 1 according to one or more embodiments of the present disclosure may include a display module 11, a processor 12, a memory 13, and a power module 14.

The display module 11 may include a display panel for displaying an image. For example, the display module 11 may include the display panel 100 according to at least one of the embodiments described above.

The processor 12 may include at least one of a central processing unit (CPU), an application processor (AP), a graphic processing unit (GPU), a communication processor (CP), an image signal processor (ISP), or a controller.

The memory 15 may store data information suitable for the operation of the processor 12 or the display module 11. The processor 12 may transmit an image data signal and/or an input control signal stored in the memory 15 to the display module 11. For example, the processor 12 executes an application stored in the memory 15, the image data signal and/or the input control signal is transmitted to the display module 11, and the display module 11 can process the received signal and output image information through a display screen.

The power module 14 may include a power supply module such as, for example, a power adapter or a battery, and a power conversion module that converts the power supplied by the power supply module to generate power suitable for the operation of the electronic device 1.

At least one of the components of the electronic device 1 according to the one or more embodiments of the present disclosure may be included in the display device according to the embodiments of the present disclosure. In addition, some modules of the individual modules functionally included in one module may be included in the display device 1, and other modules may be provided separately from the display device 1. For example, the display device 1 may include the display module 11, and the processor 12, the memory 13, and the power module 14 may be provided in the form of other devices within the electronic device 1 other than the display device 1.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a backplane substrate comprising a display area; and
a first light-emitting element layer above the backplane substrate, and comprising:
a first electrode in a first emission area of the display area;
a first light-emitting element above the first electrode; and
a first common electrode above the first light-emitting element, and comprising:
a first portion in a non-emission area surrounding the first emission area;
a second portion above at least a part of the first light-emitting element, and electrically connected to the first light-emitting element; and
a third portion between the first portion and the second portion, comprising first patterns connecting the first portion to the second portion, and defining first openings between the first patterns.

2. The display device of claim 1, wherein the first patterns are at uniform intervals in at least a part of the third portion.

3. The display device of claim 1, wherein the first openings have a planar shape of a slit shape, a mesh shape, a concentric shape, or a dot shape.

4. The display device of claim 1, wherein the display area comprises emission areas comprising the first emission area, and the non-emission area around the emission areas, and
wherein the first portion of the first common electrode is entirely in the non-emission area, and surrounds light-emitting elements in the emission areas in plan view.

5. The display device of claim 4, wherein the first common electrode has a same planar shape in the emission areas.

6. The display device of claim 4, wherein the first common electrode has different respective shapes in at least two of the emission areas for emitting light of different respective colors.

7. The display device of claim 4, wherein the first common electrode defines an opening in at least one of the emission areas for emitting light of a color that is different from that of light emitted from the first emission area.

8. The display device of claim 4, further comprising a second light-emitting element layer between the backplane substrate and the first light-emitting element layer, and comprising:
a second electrode in a second emission area of the display area;
a second light-emitting element above the second electrode; and
a second common electrode above the second light-emitting element, and comprising:
a first portion in the non-emission area;
a second portion above at least a part of the second light-emitting element, and electrically connected to the second light-emitting element; and
a third portion between the first portion and the second portion, comprising second patterns connecting the first portion to the second portion, and defining second openings between the second patterns.

9. The display device of claim 8, further comprising a first intermediate electrode connected between the backplane substrate and the first electrode, and comprising:
a first conductive layer at a same layer as, and separated from, the second electrode;
a second conductive layer at a same layer as, and separated from, the second common electrode; and
connection electrodes connecting the first conductive layer, the second conductive layer, and the first electrode.

10. The display device of claim 8, wherein the first common electrode has a same planar shape in the first emission area and in the second emission area.

11. The display device of claim 8, wherein the first common electrode has different respective planar shapes in the first emission area and in the second emission area.

12. The display device of claim 8, wherein the first common electrode and the second common electrode have a same planar shape in the second emission area.

13. The display device of claim 8, wherein the first common electrode and the second common electrode have different respective planar shapes in the second emission area.

14. The display device of claim 8, wherein the first common electrode defines at least one opening in the second emission area.

15. The display device of claim 8, further comprising a floating pattern in the second emission area at a same layer as, and separated from, the first common electrode.

16. The display device of claim 8, further comprising a third light-emitting element layer between the first light-emitting element layer and the second light-emitting element layer, and comprising:
a third electrode in a third emission area of the display area;
a third light-emitting element above the third electrode; and
a third common electrode above the third light-emitting element, and comprising:
a first portion in the non-emission area;
a second portion above at least a part of the third light-emitting element, and electrically connected to the third light-emitting element; and
a third portion between the first portion and the second portion, comprising third patterns connecting the first portion to the second portion, and defining third openings between the third patterns.

17. The display device of claim 16, further comprising a second intermediate electrode connected between the backplane substrate and the third electrode, and comprising:
a first conductive layer at a same layer as, and separated from, the second electrode;
a second conductive layer at a same layer as, and separated from, the second common electrode; and
connection electrodes connecting the first conductive layer, the second conductive layer, and the third electrode.

18. The display device of claim 16, wherein the third common electrode defines at least one opening in the second emission area.

19. The display device of claim 4, further comprising:
a power line in the non-emission area above the backplane substrate, surrounding the light-emitting elements in the emission areas in plan view, and electrically connected to the first common electrode; and
a reflective film covering a side surface of the power line.

20. An electronic device comprising:
a processor configured to transmit an image data signal; and
a display module configured to receive the image data signal, and comprising a display panel that comprises:
a backplane substrate comprising a display area; and
a first light-emitting element layer above the backplane substrate, and comprising:
a first electrode in a first emission area of the display area;
a first light-emitting element above the first electrode; and
a first common electrode above the first light-emitting element, and comprising:
a first portion in a non-emission area surrounding the first emission area;
a second portion above at least a part of the first light-emitting element, and electrically connected to the first light-emitting element; and
a third portion between the first portion and the second portion, comprising first patterns connecting the first portion to the second portion, and defining first openings between the first patterns.
